(19) United States
(12) Patent Application Publication
(10) Pub. No.: US 2026/0173493 A1
(43) Pub. Date: Jun. 18, 2026

(54) CONFIGURABLE INDUCTIVE, CAPACITIVE, AND INDUCTIVE-CAPACITIVE DEVICE ARRAYS FOR SEMICONDUCTOR DEVICES

(71) Applicant: Saras Micro Devices, Inc., Chandler, AZ (US)

(72) Inventors: John Clayton Donaghey, Scottsdale, AZ (US); Carlos Andres Riera Cercado, Atlanta, GA (US); Bartlet DeProspo, Atlanta, GA (US)

(21) Appl. No.: 18/983,079

(22) Filed: Dec. 16, 2024

(51) Int. Cl. H10D 80/20; H01L 21/48; H01L 23/13; H01L 23/373; H01L 25/18; H10D 1/20; H10D 1/68

(52) U.S. Cl. CPC H10D 80/215; H10D 1/20; H10D 1/68; H10W 70/05; H10W 70/68; H10W 90/00; H10W 40/258

(57) ABSTRACT

A customizable passive device array is fabricated by forming one or more cavities in a double-clad laminate substrate with a top conductive layer, a bottom conductive layer, and a dielectric layer between the top conductive layer and the bottom conductive layer. The substrate defines one or more separated top conductive layer segments and one or more separated bottom conductive layer segments. A dicing tape is laminated onto the double-clad laminate substrate. One or more passive devices are placed into a corresponding one of the one or more cavities, and are affixed to the dicing tape. Intermediary gaps are defined between sides of the passive devices and adjacent walls of the double-clad laminate substrate, which are then filled with a dielectric material. The dicing tape is then removed from the substrate.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND

### 1. Technical Field

The present disclosure relates generally to passive devices and passive device circuits, and more particularly, to configurable inductive, capacitive, and inductive-capacitive device arrays for semiconductor devices.

### 2. Related Art

As a general matter, a power supply is a necessary component of all electronics devices. Typical active components of digital electronic devices utilize one of several established direct current (DC) operating voltage levels that depend on the breakdown voltages of the semiconductor technology on which the device is fabricated. These include 5V rails, 3.3V rails, 1.2V rails and 0.8V rails. Accordingly, power supplies condition an input AC (line) or DC (battery) voltage to one or more of these voltage rails. One type of power down conversion circuit is the buck converter, and various implementations thereof rely upon a network of capacitors, inductors and inductor-capacitor (LC) passive components. There is a need in the art for supporting a wide range of system architectures that have different power supply requirements, which in turn involve different configurations of passive component networks. It would be desirable to integrate the passive component networks into the core of a substrate, which can be interconnected in various configurations to accommodate inductance and capacitance parameters. It would also be desirable to have heat management features in the substrate because the passive components are configured to handle increasing current draws.

### BRIEF SUMMARY

An array architecture of embedded inductors and capacitors is disclosed. The array may be completely customized for specific applications, and utilizes repeat capacitors that can be variously interconnected to support different voltage conversions in DC-DC converter circuits. Additionally, various embodiments of an inductor-capacitor (LC) module are also disclosed.

According to one embodiment, a method for fabricating a customizable passive device array may include forming one or more cavities in a double-clad laminate substrate with a top conductive layer, a bottom conductive layer, and a dielectric layer between the top conductive layer and the bottom conductive layer. The double-clad laminate substrate may define one or more separated top conductive layer segments and one or more separated bottom conductive layer segments. The method may also include laminating a dicing tape onto the double-clad laminate substrate. There may also be a step of placing one or more passive devices into a corresponding one of the one or more cavities in the double-clad laminate substrate. The passive devices may be affixed to the dicing tape. Intermediary gaps may be defined between sides of the passive devices and adjacent walls of the double-clad laminate substrate. There may be a step of filling the intermediary gaps with a dielectric material, as well as removing the dicing tape from the double-clad laminate substrate.

The method may also include placing or more electrical interconnects each on a respective one of the top conductive electrodes on the one or more passive devices. There may also be a step of establishing one or more connections of conductive terminals of one or more active devices with the electrical interconnects. This aspect may further include underfilling space between the one or more active devices and the top conductive layer segments and the passive devices.

In another aspect of the method, there may be a step of placing a thermal conduction block in one of the one or more cavities in the double-clad laminate substrate. Additional intermediary gaps may be defined between sides of the thermal conduction block and adjacent walls of the double-clad laminate substrate.

In still another aspect, the method may include placing one or more metallic passive devices in one or more cavities in the double-clad laminate substrate adjacent to the LC circuit. A given one of the one or more metallic passive devices may be either a capacitor or an inductor.

Yet another aspect of the method may include forming one or more via cavities in the double-clad laminate structure. There may also be a step of depositing conductive material along the via cavities to define vias, followed by a step of isolating each of the vias from other vias.

According to another embodiment of the present disclosure, there may be a method for fabricating a customizable passive device array. The method may include forming one or more cavities in a double-clad laminate substrate with a top conductive layer, a bottom conductive layer, and a dielectric layer between the top conductive layer and the bottom conductive layer. The double-clad laminate substrate may define one or more separated top conductive layer segments and one or more separated bottom conductive layer segments. There may additionally be a step of laminating a dicing tape onto the double-clad laminate substrate, followed by a step of placing a first passive device into a first one of the one or more cavities in the double-clad laminate substrate. The first passive device being affixed to the dicing tape. There may also be a step of stacking a second passive device and the first passive device, then there may be a step of underfilling a space between the first passive device and the second passive device. The method may also include filling intermediary gaps between a combined structure of the first passive device and the second passive device and adjacent walls of the double-clad laminate substrate defining the first cavity. There may further be a step of removing the dicing tape from the double-clad laminate substrate.

In still another embodiment of the present disclosure, there may be a configurable passive device array. The configurable device array may include a double-clad laminate substrate with a top conductive layer, a bottom conductive layer, and a dielectric layer between the top conductive layer and the bottom conductive layer. The double-clad laminate substrate may define one or more cavities separating individual top conductive layer segments and individual bottom conductive layer segments. The configurable device array may also include one or more passive devices positioned within a respective one of the one or more cavities. Each of the one or more passive devices may include a first conductive terminal coplanar with and spaced apart from adjacent ones of the top conductive layer segments. Each of the one or more passive devices may also include a second conductive terminal coplanar with and spaced apart from adjacent ones of the bottom conductive layer segments.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a flowchart illustrating steps of a method for fabricating a customizable passive device array;

FIGS. 2A-2F are cross-sectional views showing the steps of the method for fabricating a first embodiment of a customizable passive device array;

FIG. 3 is a top plan view of a customizable passive device array according to an embodiment of the present disclosure;

FIG. 4 is a top view of an embodiment of the customizable passive device array with various interconnections of inductors and capacitors;

FIG. 5 is a cross-sectional view of an integrated circuit package stack including customizable passive device arrays according to an embodiment of the present disclosure;

FIGS. 6A-6F are cross-sectional views showing the steps of the method for fabricating a second embodiment of a customizable passive device array;

FIG. 7 is a top view of an embodiment of the customizable passive device array with various interconnections of inductors to accommodate different voltage rails;

FIG. 8 is a top view of an embodiment of the customizable passive device array with various interconnections of inductors;

FIG. 9 is a cross-sectional view of an integrated circuit package stack including customizable passive device arrays according to another embodiment of the present disclosure;

FIGS. 10A-10F are cross-sectional views showing the steps of the method for fabricating a third embodiment of a customizable passive device array;

FIG. 11 is a top view of an embodiment of the customizable passive device array with various interconnections of capacitors to accommodate different voltage rails;

FIG. 12 is a top view of an embodiment of the customizable passive device array with various interconnections of capacitors;

FIGS. 13A-13I are cross-sectional views showing the steps of the method for fabricating a fourth embodiment of a customizable passive device array;

FIG. 14 is a top view of an active device and passive array stack with one embodiment of the customizable passive device array and active devices stacked thereon;

FIG. 15 is a circuit diagram of an exemplary buck converter circuit in which a vertical inductor-capacitor (LC) module may be utilized;

FIGS. 16A-16F are cross-sectional views showing the steps of the method for fabricating a fifth embodiment of a passive device array;

FIGS. 17A-17D are cross sectional views showing the steps of fabricating a vertical LC module at various stages of completion;

FIG. 18 is a top view of the customizable passive device array according to a fifth embodiment of the present disclosure;

FIGS. 19A-19F are cross-sectional views showing the steps of the method for fabricating a sixth embodiment of a passive device array;

FIG. 20 is a top view of a single dimension passive device array configured in accordance with the sixth embodiment;

FIG. 21 is a top view of a two-dimension passive device array configured in accordance with the sixth embodiment;

FIGS. 22A-22H are cross-sectional views showing the steps of an alternative method for fabricating the sixth embodiment of a passive device array;

FIGS. 23A-23I are cross-sectional views showing the steps of a method for fabricating the seventh embodiment of a passive device array;

FIG. 24 is a top view of a single dimension passive device array configured in accordance with the seventh embodiment;

FIG. 25 is a top view of a two-dimension passive device array configured in accordance with the seventh embodiment;

FIGS. 26A-26H are cross-sectional views showing the steps of a method for fabricating an eighth embodiment of a passive device array;

FIG. 27 is a top view of a single dimension passive device array configured in accordance with the eighth embodiment;

FIG. 28 is a perspective view of a ninth embodiment of a passive device array;

FIGS. 29A-29I are cross-sectional views showing the steps of a method for fabricating the ninth embodiment of a passive device array;

FIG. 30 is a top view of a single dimension passive device array configured in accordance with the ninth embodiment; and

FIG. 31 is a top view of a two-dimension passive device array configured in accordance with the tenth embodiment.

### DETAILED DESCRIPTION

The detailed description set forth below in connection with the appended drawings is intended as a description of the several presently contemplated embodiments of configurable inductive, capacitive, and inductive-capacitive device arrays and is not intended to represent the only form in which such embodiments may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second, left and right, top and bottom, and the like are used solely to distinguish one from another entity without necessarily requiring or implying any actual such relationship or order between such entities.

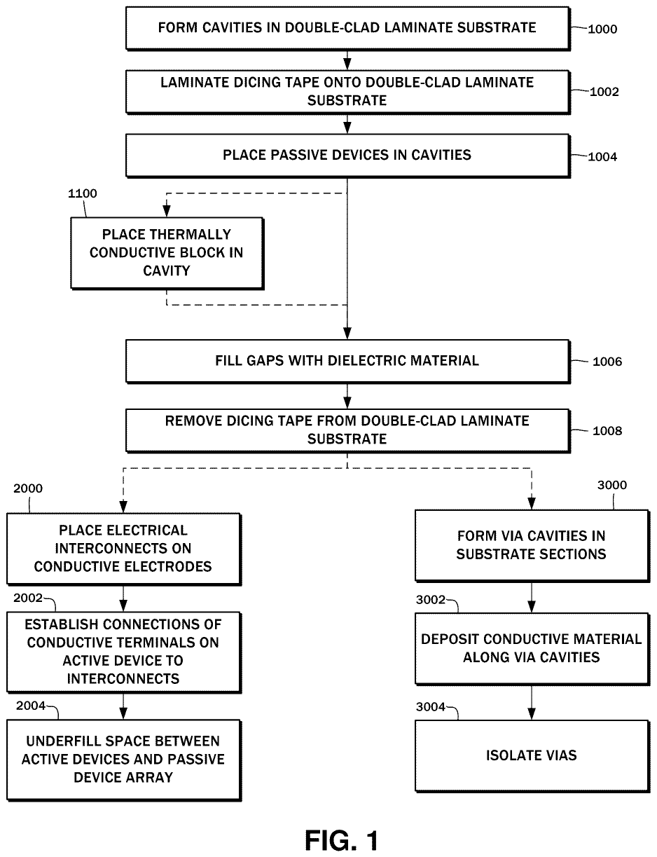

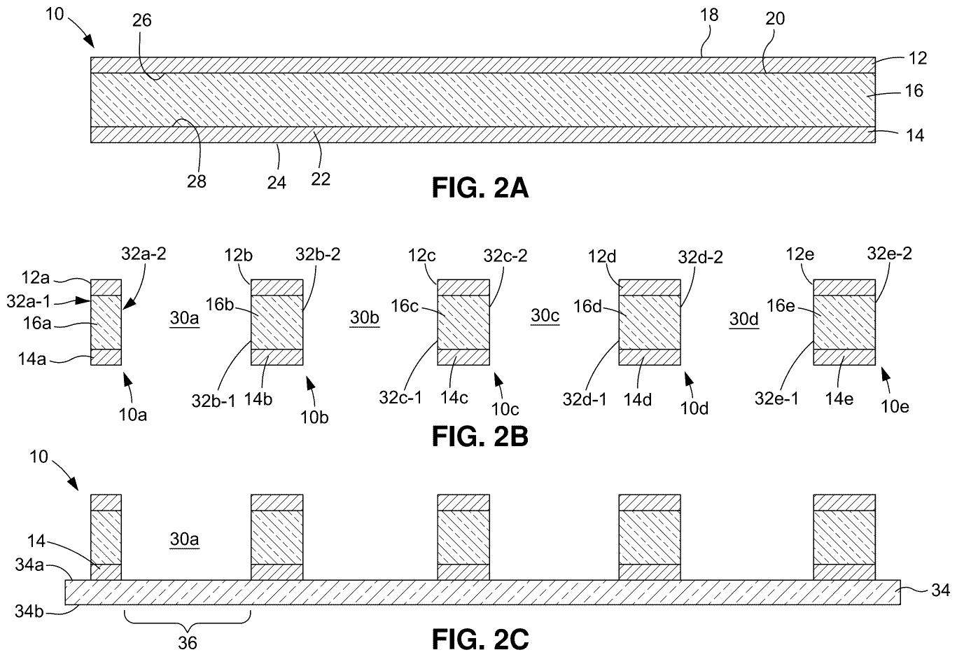

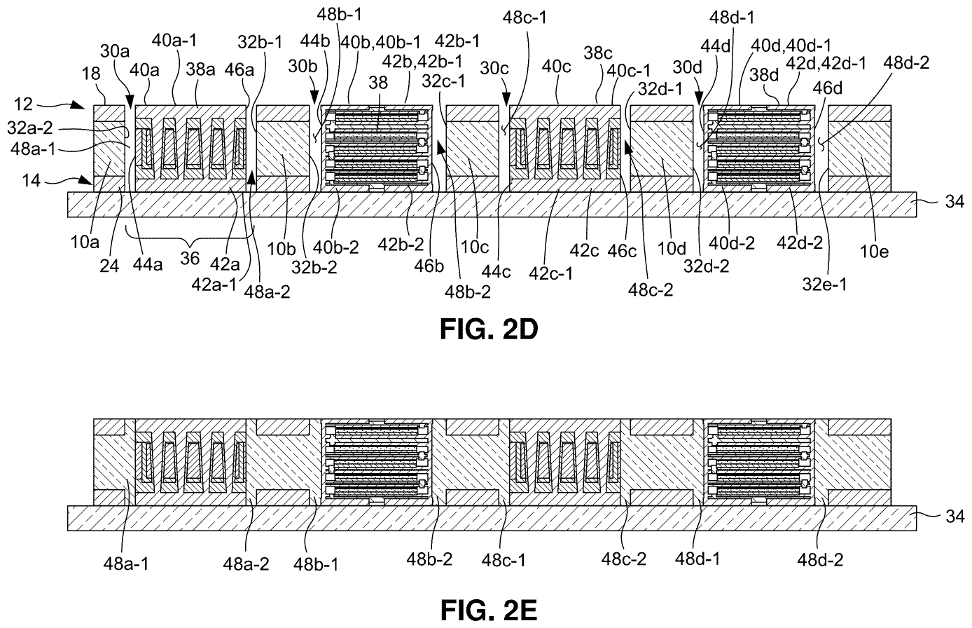

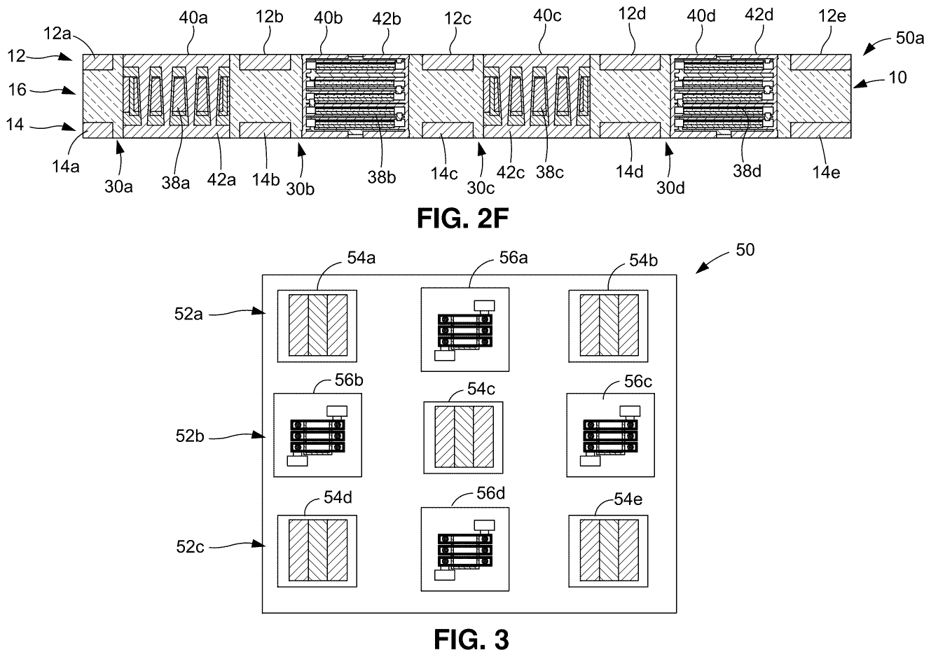

One embodiment of the present disclosure is a method for fabricating a customizable passive device array that may be comprised of discrete capacitors and inductors that are embedded into a substrate core. Repeat components may be utilized for simplifying the embedding process. The flowchart of FIG. 1 shows the sequence of steps in this method, while the cross-sectional views of FIGS. 2A-2F depict the components of the passive device array at various stages of completion. Specifically, FIG. 2A is a cross-sectional view of a double-clad laminate substrate 10 that may be processed to result in the passive device array. There is a top conductive layer 12, an opposed bottom conductive layer 14, and a dielectric layer 16 between the top conductive layer 12 and the bottom conductive layer 14. The top conductive layer 12 is defined by an exposed upper surface 18 and an opposed lower surface 20 that faces the dielectric layer 16. The bottom conductive layer 14 is similarly defined by an upper surface 22 and an opposed, exposed lower surface 24. Along these lines, the dielectric layer 16 is defined by an upper surface 26 and an opposed lower surface 28. The lower surface 20 of the top conductive layer 12 faces the upper surface 26 of the dielectric layer 16, while the upper surface 22 of the bottom conductive layer 14 faces the lower surface 28 of the dielectric layer 16.

The method begins with a step 1000 of forming one or more cavities 30 in the double-clad laminate substrate 10. In the illustrated example shown in FIG. 2B, there is a first cavity 30a, a second cavity 30b, a third cavity 30c, and a fourth cavity 30d. The formation of the cavities 30 results in the top conductive layer 12, the bottom conductive layer 14 being segregated into conductive layer segments. Because the cavities 30 extend through the entire depth of the substrate 10, the dielectric layer 16 is likewise understood to be segregated into different segments. Adjacent to the first cavity 30a and defining a left side boundary thereof is a first top conductive layer segment 12a, a first bottom conductive layer segment 14a, and a first dielectric layer segment 16a, collectively referred to as a first substrate segment 10a. The first substrate segment 10a thus defines a right sidewall 32a-2 that defines the left side boundary of the first cavity 30a. Although an opposing left sidewall 32a-1 of the first substrate segment 10a is illustrated, this is by example only and not of limitation, because the length of the double-clad laminate substrate 10 is indeterminate.

Also adjacent to the first cavity 30a but defining a right-side boundary thereof is a second top conductive layer segment 12b, a second bottom conductive layer segment 14b, and a second dielectric layer segment 16b, which collectively define a second substrate segment 10b. The second substrate segment 10b thus defines a right sidewall 32b-1 corresponding to the right-side boundary of the first cavity 30a.

The second cavity 30b is adjacent to the second substrate segment 10b, with a left sidewall 32b-2 thereof defining the left boundary of the second cavity 30b. The right-side boundary of the second cavity 30b is adjacent to a third substrate segment 10c comprised of a third top conductive layer segment 12c, a third bottom conductive layer segment 14c, and a third dielectric layer segment 16c. The third substrate segment 10c is thus defined by a left sidewall 32c-1 and a right sidewall 32c-2. The left sidewall 32c-1 defines the right-side boundary of the second cavity 30b.

The third cavity 30c is adjacent to the third substrate segment 10c as well as a fourth substrate segment 10d that includes a fourth top conductive layer segment 12d, a fourth bottom conductive layer segment 14d, and a fourth dielectric layer segment 16d. The fourth substrate segment 10d is defined by a left sidewall 32d-1 and a right sidewall 32d-2. The right sidewall 32c-2 of the third substrate segment 10c defines the left side boundary of the third cavity 30c, while the left sidewall 32d-1 of the fourth substrate segment 103 defines the right-side boundary of the fourth cavity 30d.

The fourth cavity 30d is further defined by a fifth substrate segment 10e with a fifth top conductive layer segment 12e, a fifth bottom conductive layer segment 14e, and a fifth dielectric layer segment 16e. Together, these elements define a left sidewall 32e-1 that corresponds to the right side boundary of the fourth cavity 30d. Similar to the left sidewall 32a-1 of the first substrate segment 10a, a right sidewall 32e-2 of the fifth substrate segment 10e is shown by example only because the length of the substrate 10 and hence the fifth substrate segment 10e is indeterminate and can extend at an arbitrary length.

The present disclosure makes interchangeable reference to the substrate 10 and its individual segments 10a-10e, as well as its constituent top conductive layer 12 and its segments 12a-12e, bottom conductive layer 14 and its segments 14a-14e, and dielectric layer 16 and its segments 16a-16e. It is to be understood that reference to the broader feature, e.g., the substrate 10, is to encompass one, multiple, or all of the segments, e.g., substrate segments 10a-10e, and vice versa. Specific reference to a segment may be made where necessary to describe a feature unique thereto. However, reference to the broader feature may be made to the extent the description is applicable to all of the constituent segments. The illustrated embodiments with the four cavities 30a-30d, the substrate segments 10a-10e, and the corresponding left and right sidewalls 32 are also presented by way of example only and not of limitation. Any number of cavities 30 may be formed in the substrate 10 as needed for a specific configuration, with any additional or cavities 30 resulting in additional substrate segments 10a-10e and sidewalls 32 thereof.

Referring back to the flowchart of FIG. 1 as well as the cross-sectional view of FIG. 2C, the method continues with a step 1002 of laminating a dicing tape 34 onto the double-clad laminate substrate 10. This step may also be referred to generally as back-side lamination. The dicing tape 34 may be of any suitable material such as polyvinylchloride or polyethylene and defined by an adhesive top surface 34a and an opposed bottom surface 34b. The lower surface 24 of each of the bottom conductive layer segments 14a-14e is adhered to the top surface 34a of the dicing tape 34. Because of the cavities 30, there may be exposed portions 36 of the dicing tape 34 that can accept and adhere to additional components positioned within the cavities 30, as will be described in further detail below.

Next, the method continues with a step 1004 of placing one or more passive devices 38 into a corresponding one of the cavities 30a-30d in the substrate 10. The passive devices 38 are affixed to the dicing tape 34 at the exposed portions 36 of the dicing tape 34. In further detail, the passive devices 38 include a first inductor 38a placed in the first cavity 30a, a first capacitor 38b placed in the second cavity 30b, a second inductor 38c placed in the third cavity 30c, and a second capacitor 38d.

The first inductor 38a includes a first conductive electrode 40a defined by an upper surface 40a-1 that is coplanar with the upper surface 18 of the top conductive layer 12, as well as a second conductive electrode 42a defined by a lower surface 42a-1 that is coplanar with the lower surface 24 of the bottom conductive layer 14. Likewise, the second inductor 38c includes a first conductive electrode 40a with an upper surface 40c-1 that is coplanar with the upper surface 18 of the top conductive layer 12, and a second conductive electrode 42c with a lower surface 42c-1 that is coplanar with the lower surface 24 of the bottom conductive layer 14.

The first capacitor 38b includes a first or left conductive electrode 40b, and a second or right conductive electrode 42b. Both of the first and second conductive electrodes 40b, 42b has an exposed top surface segment 40b-1, 42b-1, respectively, that are coplanar with the upper surface 18 of the top conductive layer 12, and an exposed bottom surface segment 40b-2, 42b-2, respectively, that are coplanar with the lower surface 24 of the bottom conductive layer 14. The first or left conductive electrode 40b may be a cathode while the second or right conductive electrode 42b may be an anode.

The second capacitor 38d includes a first or left conductive electrode 40d, and a second or right conductive electrode 42d. Both of the first and second conductive electrodes 40d, 42d has an exposed top surface segment 40d-1, 42d-1, respectively, that are coplanar with the upper surface 18 of the top conductive layer 12, and an exposed bottom surface segment 40d-2, 42d-2, respectively, that are coplanar with the lower surface 24 of the bottom conductive layer 14.

The first inductor 38a is defined by a left sidewall 44a and a right sidewall 46a. The left sidewall 44a opposes and is spaced apart from the right sidewall 32a-2 of the first substrate segment 10a, defining a left cavity gap 48a-1. The right sidewall 46a opposes and is spaced apart from the left sidewall 32b-1 of the second substrate segment 10b, defining a right cavity gap 48a-2. The cavity caps 48 may also be referred to as intermediary gaps.

The first capacitor 38b is similarly defined by a left sidewall 44b and a right sidewall 46b. As indicated above, the first capacitor 38b is positioned within the second cavity 30b, so the left sidewall 44b opposes and is spaced apart from the right sidewall 32b-2 of the second substrate segment 10b, while the right sidewall 46b opposes and is spaced apart from the left sidewall 32c-1 of the third substrate segment 10c. Between the left sidewall 44b and the right sidewall 32b-2, a left cavity gap 48b-1 is defined, and between the right sidewall 46b and the left sidewall 32c-1, a right cavity gap 48b-2 is defined.

The second inductor 38c is defined by a left sidewall 44c and a right sidewall 46c and is disposed in the third cavity 30c. The left sidewall 44c opposes and is spaced apart from the right sidewall 32c-2 of the third substrate segment 10c, defining a left cavity gap 48c-1. The right sidewall 46c opposes and is spaced apart from the left sidewall 32d-1 of the fourth substrate segment 10d, defining a right cavity gap 48c-2.

The second capacitor 38d is defined by a left sidewall 44d and a right sidewall 46d, and is positioned within the fourth cavity 30d. Thus, the left sidewall 44d opposes and is spaced apart from the right sidewall 32d-2 of the fourth substrate segment 10d, and the right sidewall 46b opposes and is spaced apart from the left sidewall 32e-1 of the fifth substrate segment 10e. Between the left sidewall 44d and the right sidewall 32d-2, a left cavity gap 48d-1 is defined, and between the right sidewall 46d and the left sidewall 32e-1, a right cavity gap 48d-2 is defined.

Once the passive devices 38 are placed within the cavities 30, as shown in FIG. 2E, the method continues with a step 1006 of filling the intermediary or cavity gaps 48 with a dielectric material. Thereafter, the method proceeds to a step 1008 of removing the dicing tape 34. FIG. 2F shows a first embodiment of a passive device array 50a according to one embodiment of the present disclosure, which includes the double-clad laminate substrate 10 with the top conductive layer 12, the bottom conductive layer 14, and the dielectric layer 16. As described above, one or more passive devices 38a-38d are positioned within the respective cavities 30a-30d, with each of the passive devices including a first conductive terminal or electrode 40a-40d and a second conductive terminal or electrode 42a-42d. As shown, the first conductive electrodes 40a-40d are spaced apart from the top conductive layer segments 12a-12e, and the second conductive electrodes 42a-42d are spaced apart from the bottom conductive layer segments 14a-14e.

Although FIGS. 2A-2F depict a single row of passive devices 38, the passive device array 50 need not be limited thereto. FIG. 3 is a top plan view of a 3×3 array, with a first row 52a including a first capacitor 54a, a first inductor 56a, and a second capacitor 54b, a second row 52b including a second inductor 56b, a third capacitor 54c, and a third inductor 56c, and a third row 52c including a fourth capacitor 54d, a fourth inductor 56d, and a fifth capacitor 54e. Because of the mix of capacitors 54 and inductors 56, this configuration may be referred to as a field programmable passives array (FPPA). In this regard, the embodiments of the present disclosure contemplate the interconnection of the passive devices 38 by a downstream integrated circuit developer that tailors to the passive device array 50 a specific application. For example, the capacitors 54 and the inductors 56 may be connected in series to provide increased inductance, or to complete an inductor-capacitor (LC) circuit for DC-DC converters. As will be described in further detail below, each LC circuit is capable of supporting different voltage down-conversion requirements. The specifics of the placement of each capacitor 54 and inductor 56 are dependent on the signal phase requirements, whether that be four, eight, sixteen, or thirty-two phases.

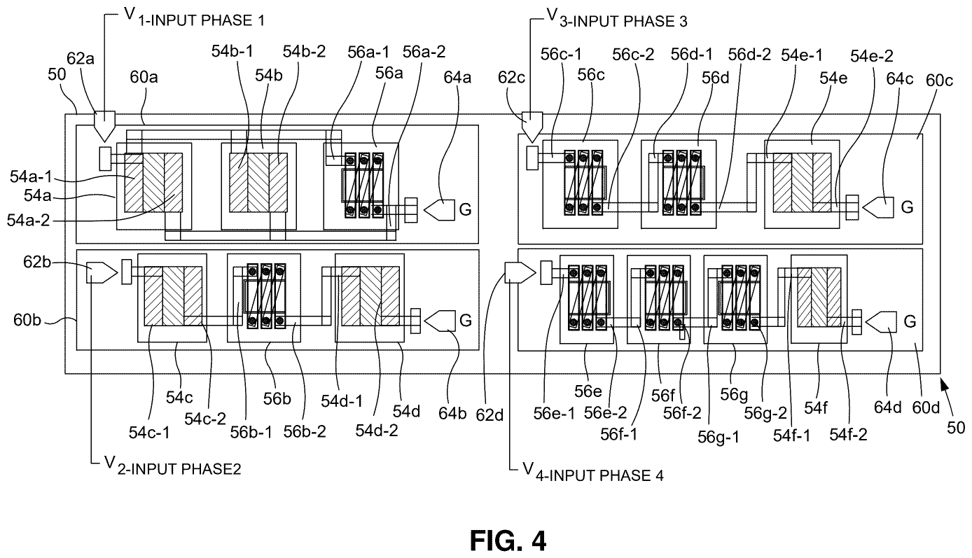

Referring now to the diagram of FIG. 4, the passive device array 50 may be configured to support different voltage rails, with each voltage input and output being connectible to various LC modules 60, depending on system architecture and decoupling needs therefor. An exemplary first LC module 60a includes a first capacitor 54a, a second capacitor 54b, and a first inductor 56a, with a first LC module input port 62a and a first LC module output port 64a. The first capacitor 54a includes a first terminal 54a-1 that is connected to the first LC module input port 62a, as well as a second terminal 54a-2. The second capacitor 54b includes a first terminal 54b-1 and a second terminal 54b-2, and the first inductor 56a includes a first terminal 56a-1 and a second terminal 56a-2 that is connected to the second LC module output port 64b. The first and second capacitors 54a, 54b and the first inductor 56a are connected in parallel, so the first terminal 54a-1 of the first capacitor 54a, the first terminal 54b-1 of the second capacitor 54b, and the first terminal 56a-1 of the first inductor 56a are tied together and connected to the first LC module input port 62a, and the second terminal 54a-2 of the first capacitor 54a, the second terminal 54b-2 of the second capacitor 54b, and the second terminal 56a-2 of the first inductor 56a are tied together and connected to the first LC module output port 64a.

The exemplary second LC module 60b includes a third capacitor 54c, a second inductor 56b, and a fourth capacitor 54d. The third capacitor 54c has a first terminal 54c-1 connected to the second LC module input port 62b, and a second terminal 54c-2. The second inductor 56b has a first terminal 54b-1 and a second terminal 54b-2, and the fourth capacitor 54d includes a first terminal 54d-1 and a second terminal 54d-2. The third capacitor 54c is connected in series with the second inductor 56b, which in turn is connected in series with the fourth capacitor 54d. To this end, the second terminal 54c-2 of the third capacitor 54c is connected to the first terminal 56b-1 of the second inductor 56b. Furthermore, the first terminal 54d-1 of the fourth capacitor 54d is connected to the second terminal 56b-2 of the second inductor 56b. The second terminal 54d-2 of the fourth capacitor 54d is connected to the second LC module output port 64b.

The exemplary third LC module 60c includes a third inductor 56c, a fourth inductor 56d, and a fifth capacitor 54e. The third inductor 56c has a first terminal 56c-1 connected to the third LC module input port 62c, and a second terminal 56c-2. The fourth inductor 56d has a first terminal 56d-1 and a second terminal 56d-2, and the fifth capacitor 54e includes a first terminal 54e-1 and a second terminal 54e-2. The third inductor 56c is connected in series with the fourth inductor 56d, which in turn is connected in series with the fifth capacitor 54e. The second terminal 56c-2 of the third inductor 56c is connected to the first terminal 56d-1 of the fourth inductor 56d, and the second terminal 56d-2 of the fourth inductor 56d is connected to the first terminal 54e-1 of the fifth capacitor 54e. The second terminal 56e-2 of the fifth capacitor 54e is connected to the third LC module output port 64c.

The exemplary fourth LC module 60d includes a fifth inductor 56e, a sixth inductor 56f, a seventh inductor 56g, and a sixth capacitor 54f. The fifth inductor 56e has a first terminal 56e-1 connected to the fourth LC module input port 62d, and a second terminal 56e-2. The sixth inductor 56f has a first terminal 56f-1 and a second terminal 56f-2, the seventh inductor 56g has a first terminal 56g-1 and a second terminal 56g-2, and the sixth capacitor 54f includes a first terminal 54f-1 and a second terminal 54f-2. The capacitors 54 and inductors 56 in the fourth LC module 60d are connected in series, so the second terminal 56e-2 of the fifth inductor 56e is connected to the first terminal 56f-1 of the sixth inductor 56f. In turn, the second terminal 56f-2 of the sixth inductor 56f is connected to the first terminal 56g-1 of the seventh inductor 56g, and second terminal 56g-2 of the seventh inductor 56g is connected to the first terminal 54f-1 of sixth capacitor 54f. The second terminal 54f-2 of the sixth capacitor 54f is connected to the fourth LC module output port 64d.

Each of the LC modules 60 is understood to correspond to a specific voltage rail. The properties and architecture of each of the LC modules 60 may be identical or different from one another. The aforementioned parallel and series connections are understood to be defined through redistribution layers (RDLs). It is understood that each of the interconnections of the passive devices 54, 56 in the LC modules 60a-60d are presented by way of example only and not of limitation. Each LC module 60 may be configured according to the specifics of the application and are not limited to that which is shown and described above.

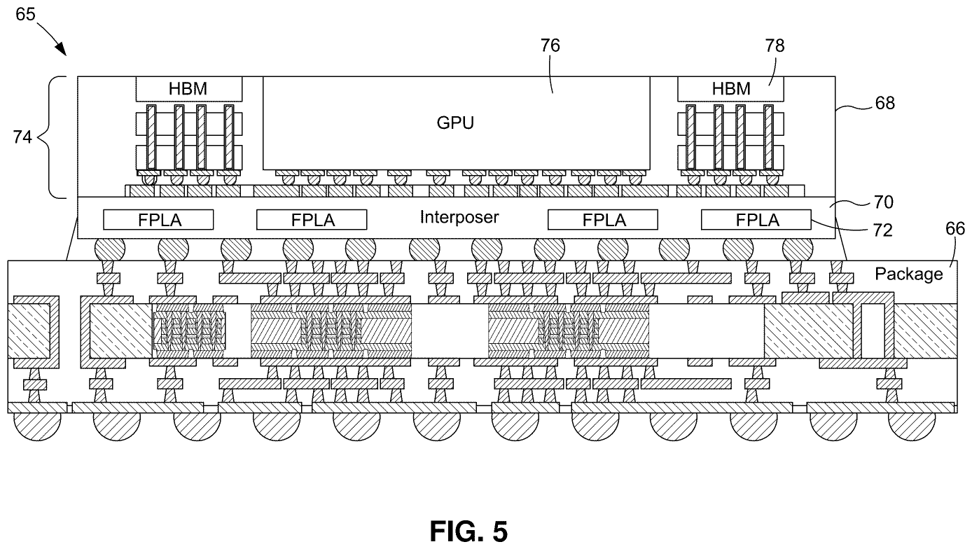

Referring to FIG. 5, an integrated circuit package stack 65 has a first ball grid array (BGA) package 66, onto which a second BGA package 68 is stacked. The second BGA package 68 includes an interposer 70 with a series of field programmable inductor arrays 72 (FPLA) that connected to an integrated circuit 74. The specifics of the integrated circuit 74 are not pertinent to the embodiments of the present disclosure and may be any device that requires an interconnection of various inductors. However, for the sake of example, there may be a graphics processing unit (GPI) 76 and high-bandwidth memory (HBM) 78.

The field programmable inductor array 72, which may also be referred to as a second embodiment of the passive device array 50b, is comprised of discrete inductors embedded into the substrate core. The method for fabrication is the same as discussed above in relation to the first embodiment of the passive device array 50a, except that the passive devices 38 are only inductors rather than inductors and capacitors. In describing the second embodiment of the passive device array 50b and the method for fabricating the same, those details described above in relation to the first embodiment that are shared with the second embodiment will not be repeated for the sake of brevity.

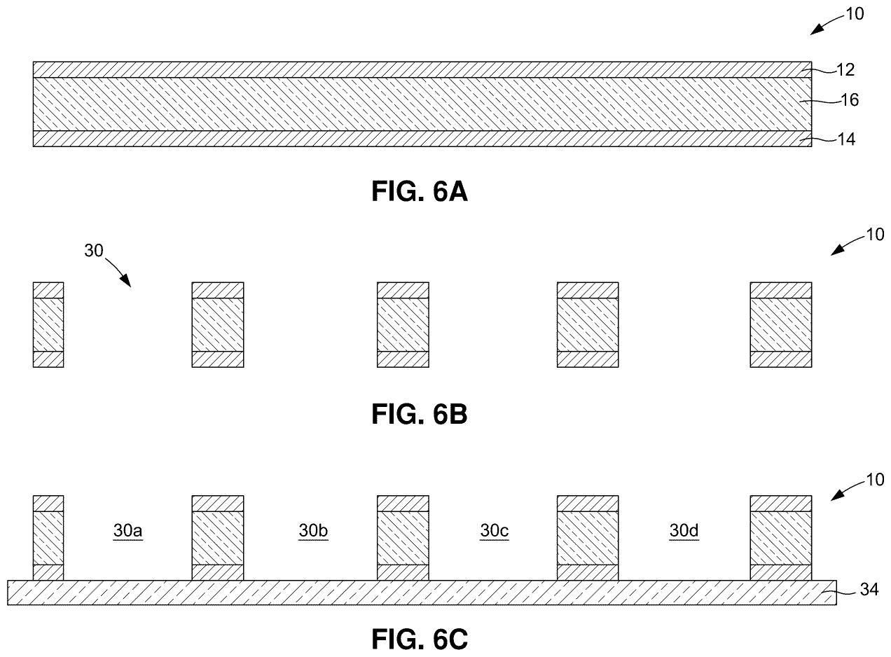

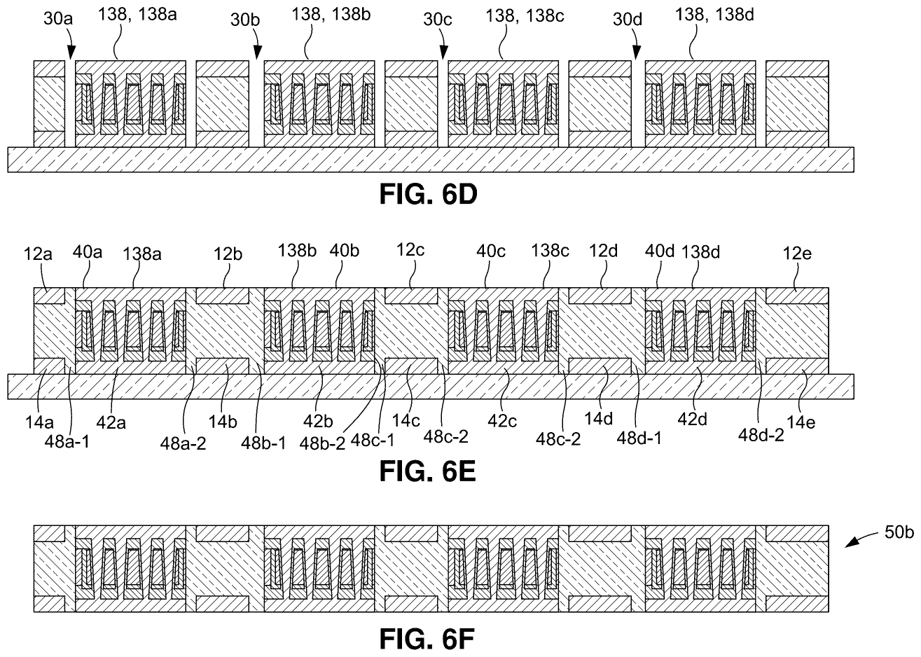

FIG. 6A-6F illustrate the components of the passive device array 50b at various stages of completion, with FIG. 6A showing the same double-clad laminate substrate 10 defined by the top conductive layer 12, the bottom conductive layer 14, and the dielectric layer 16 between the top conductive layer 12 and the bottom conductive layer 14. As in the first embodiment, the method begins with the step 1000 of forming the cavities 30 in the double-clad laminate substrate 10, which is best illustrated in FIG. 6B. Next, as shown in FIG. 6C, the dicing tape 34 is laminated onto the double-clad laminate substrate 10 in accordance with step 1002. FIG. 6D shows the next step 1004 of placing the passive devices 138 into the respective cavities 30. In further detail, a first inductor 138a is placed in the first cavity 30a, a second inductor 138b is placed in the second cavity 30b, a third inductor 138c is placed in the third cavity 30c, and a fourth inductor 138d is placed in the fourth cavity 30d. Next, as shown in FIG. 6E, the cavity gaps 48 are filled with the dielectric material according to step 1006.

The first inductor 138a includes the first conductive electrode 40a that is spaced apart from the adjacent first top conductive layer segment 12a and the second top conductive layer segment 12b. The first inductor 138a also includes the second conductive electrode 42a spaced apart from the adjacent first bottom conductive layer segment 14a and the second bottom conductive layer segment 14b. The second inductor 138b includes the first conductive electrode 40b and the second conductive electrode 42b, which are spaced apart from the second top conductive layer segment 12b and the second bottom conductive layer segment 14b, respectively, as well as the third top conductive layer segment 12c and the third bottom conductive layer segment 14c, respectively. The third inductor 138c includes the first conductive electrode 40c and the second conductive electrode 42c, which are spaced apart from the third top conductive layer segment 12c and the third bottom conductive layer segment 14c, respectively, and the fourth top conductive layer segment 12d and the fourth bottom conductive layer segment 14d, respectively. Lastly, the fourth inductor 138d includes the first conductive electrode 40d and the second conductive electrode 42d, which are spaced apart from the fourth top conductive layer segment 12d and the fourth bottom conductive layer segment 14d, respectively, and the fifth top conductive layer segment 12e and the fifth bottom conductive layer segment 14e, respectively. FIG. 6F illustrates the completed passive device array 50b after step 1008 of removing the dicing tape 34 from the double-clad laminate substrate 10.

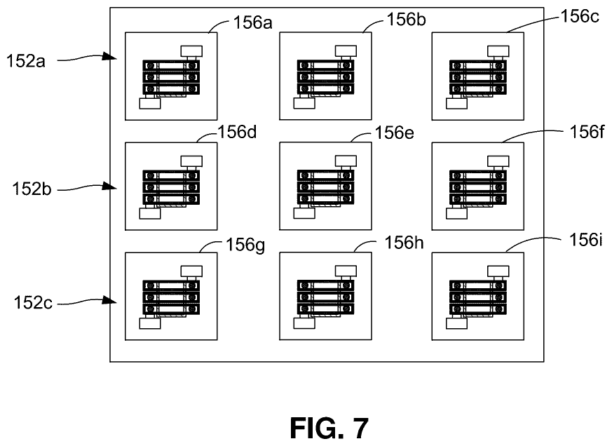

Again, the passive device array 50b need not be limited to a single row of passive devices 138. FIG. 7 is a top plan view of a 3×3 array, with a first row 152a including a first inductor 156a, a second inductor 156b, and a third inductor 156c. A second row 152b includes a fourth inductor 156d, a fifth inductor 156e, and a sixth inductor 156f. A third row 152c includes a seventh inductor 156g, an eighth inductor 156h, and a ninth inductor 156i. The embodiments of the present disclosure contemplate the interconnection of the passive devices 138 by a downstream integrated circuit developer that tailors to the passive device array 50 a specific application.

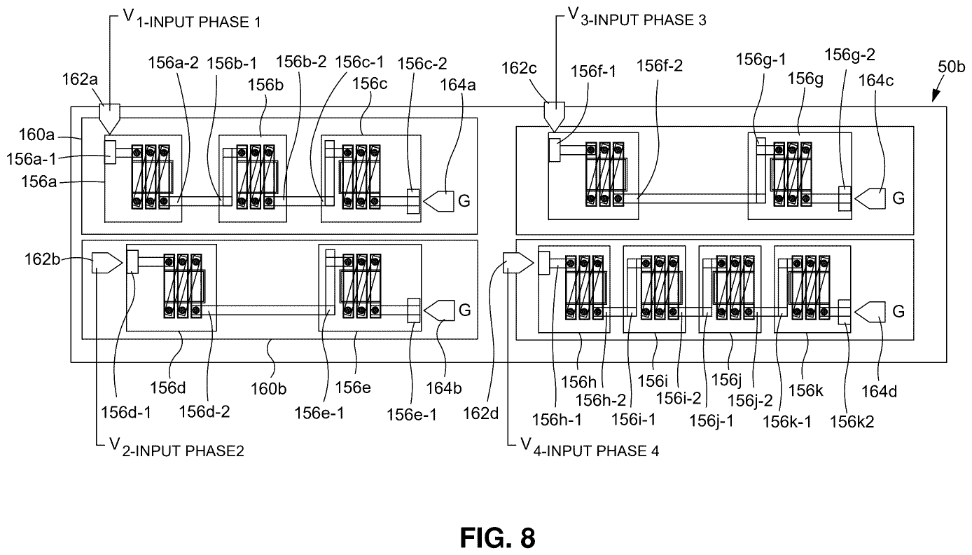

FIG. 8 illustrates the second embodiment of the passive device array 50b that is configured to support different voltage rails, with each voltage input and output being connectible to various inductor modules 160, depending on system architecture and decoupling needs therefor. An exemplary first inductor module 160a includes a first inductor 156a, a second inductor 156b, and a third inductor 156c, with a first inductor module input port 162a and a first inductor module output port 164a. The first inductor 156a includes a first terminal 156a-1 that is connected to the first inductor module input port 162a, as well as a second terminal 156a-2. The second inductor 156b includes a first terminal 156b-1 and a second terminal 156b-2, and the third inductor 156c includes a first terminal 156c-1 and a second terminal 156c-2 that is connected to the first inductor module output port 164a. Each of the inductors 156 are connected in series, meaning that the second terminal 156a-2 of the first inductor 156a is connected to the first terminal 156b-1 of the second inductor 156b, and the second terminal 156b-2 of the second inductor 156b is connected to the first terminal 156c-1 of the third inductor 156c.

An exemplary second inductor module 160b includes a fourth inductor 156d and a fifth inductor 156e. The fourth inductor 156d has a first terminal 156d-1 connected to the second inductor module input port 162b, and a second terminal 156d-2. The fifth inductor 156e has a first terminal 156e-1 and a second terminal 156e-2 that is connected to the second inductor module output port 164b. The fourth inductor 156d is connected in series with the fifth inductor 156e, so the second terminal 156d-2 of the fourth inductor 156d is connected to the first terminal 156e-1 of the fifth inductor 156e.

An exemplary third inductor module 160c includes a sixth inductor 156f and a seventh inductor 156g. The sixth inductor 156f has a first terminal 156f-1 connected to the third inductor module input port 162c, and a second terminal 156f-2. The seventh inductor 156g has a first terminal 156g-1 and a second terminal 156g-2 that is connected to the third inductor module output port 164c. The sixth inductor 156f is connected in series with the seventh inductor 156g, so the second terminal 156f-2 of the sixth inductor 156f is connected to the first terminal 156g-1 of the seventh inductor 156g.

An exemplary fourth inductor module 160d includes an eighth inductor 156h, a ninth inductor 156i, a tenth inductor 156j, and an eleventh inductor 156k. The eighth inductor 156h has a first terminal 156h-1 connected to the fourth inductor module input port 162d, and a second terminal 156h-2. The ninth inductor 156i has a first terminal 156l-1 connected to the second terminal 156h-2 of the eighth inductor 156h, and a second terminal 156i-2. The tenth inductor 156j has a first terminal 156j-1 connected to the second terminal 156l-2 of the ninth inductor 156i, and a second terminal 156j-2. The eleventh inductor 156k, in turn, has a first terminal 156k-1 connected to the second terminal 156j-2 of the tenth inductor 156j, and a second terminal 156k-2 connected to the fourth inductor module output port 164d. Thus, the eighth inductor 156h is connected in series with the ninth inductor 156i, which in turn is connected in series with the tenth inductor 156j, which in turn is connected in series with the eleventh inductor 156k.

Each of the interconnections of the inductors 156 in the inductor modules 160a-160d are presented by way of example only and not of limitation. Each inductor module 160 may be configured according to the specifics of the application and are not limited to that which is shown and described above. Again, each of the inductor modules 160 is understood to correspond to a specific voltage rail. The properties and architecture of each of the inductor modules 160 may be identical or different from one another, as illustrated. The aforementioned connections are understood to be defined through RDLs, and as depicted the connection configurations of the inductor modules 160a-160d, the inductance per mm² may be increased.

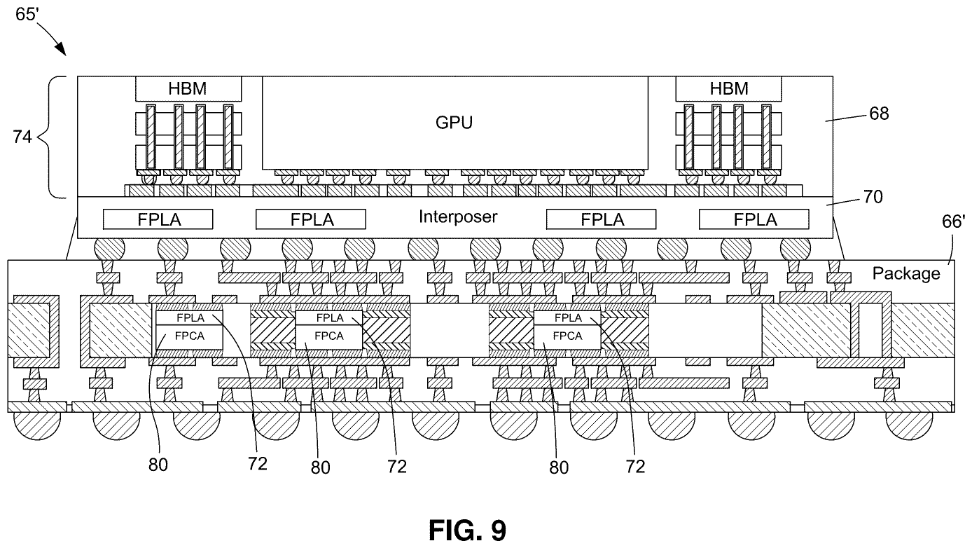

FIG. 9 depicts another embodiment of the integrated circuit package stack 65′ that is comprised of an alternative first ball grid array (BGA) package 66′, onto which the second BGA package 68 is stacked. As indicated above, the second BGA package 68 includes the interposer 70 with a series of field programmable inductor arrays 72 (FPLA) that connected to the integrated circuit 74. Again, the specifics of the integrated circuit 74 are not pertinent to the embodiments of the present disclosure and may be any device that requires an interconnection of various inductors. In the first BGA package 66′ the field programmable inductor arrays 72 are incorporated, as well as a series of field programmable capacitor arrays 80 that may also be referred to as a third embodiment of the passive device array 50c with discrete capacitors embedded into the substrate core. The method for fabrication is the same as discussed above in relation to the first and second embodiments of the passive device array 50a, 50b, except that the passive devices 38 are only capacitors rather that inductors and capacitors, or just inductors. In describing the third embodiment of the passive device array 50c and the method for fabricating the same, those details described above in relation to the first and second embodiments that are shared with the third embodiment will not be repeated for the sake of brevity.

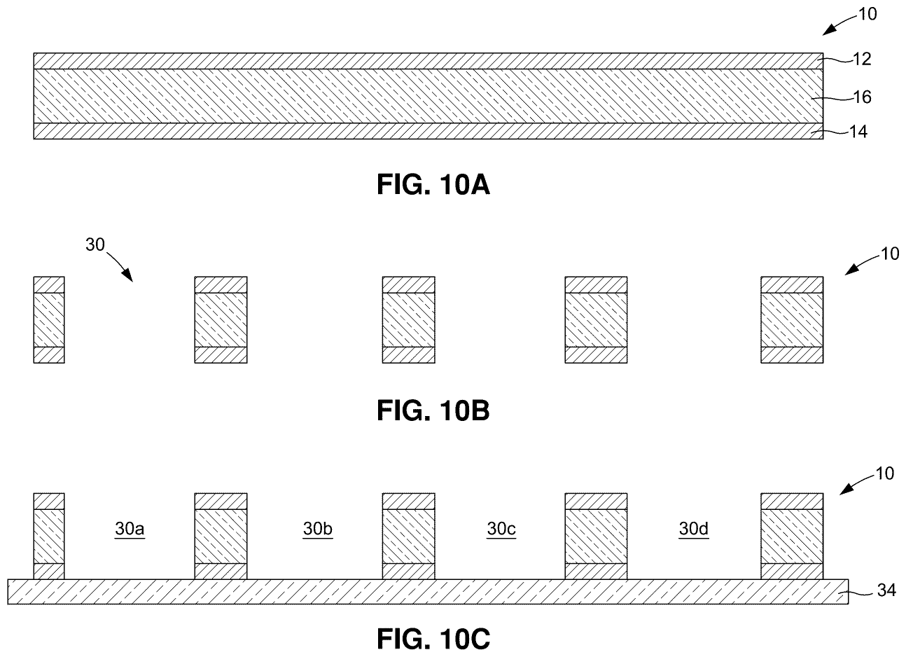

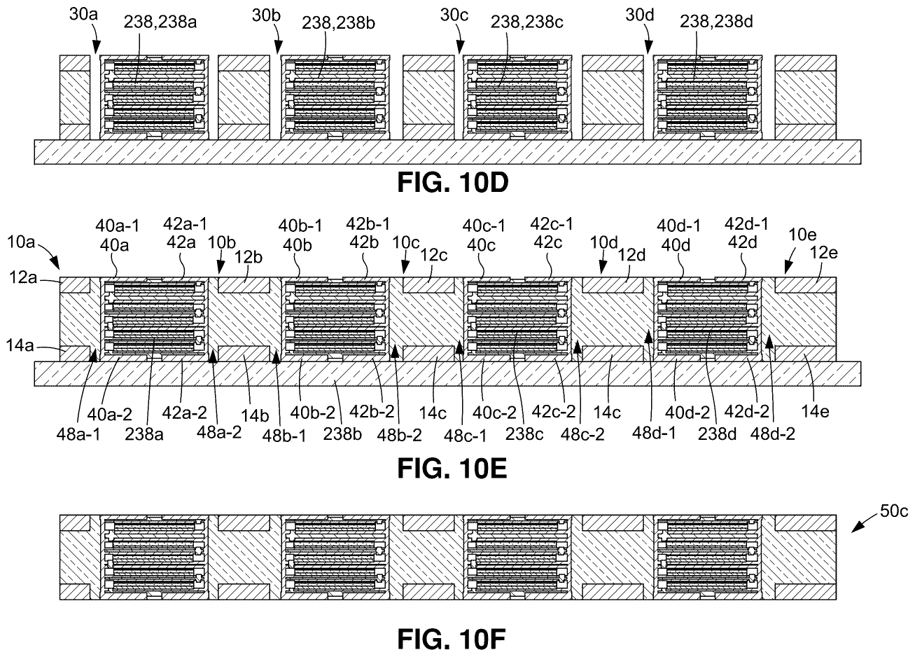

FIG. 10A-10F illustrate the components of the passive device array 50c at various stages of completion, with FIG. 10A showing the same double-clad laminate substrate 10 defined by the top conductive layer 12, the bottom conductive layer 14, and the dielectric layer 16 between the top conductive layer 12 and the bottom conductive layer 14. As in the first and second embodiments, the method begins with the step 1000 of forming the cavities 30 in the double-clad laminate substrate 10, which is best illustrated in FIG. 10B. FIG. 10C then shows the dicing tape 34 laminated onto the double-clad laminate substrate 10 in accordance with the step 1002. FIG. 10D shows the next step 1004 of placing the passive devices 238 into the respective cavities 30. In further detail, a first capacitor 238a is placed in the first cavity 30a, a second capacitor 238b is placed in the second cavity 30b, a third capacitor 238c is placed in the third cavity 30c, and a fourth capacitor 238d is placed in the fourth cavity 30d. Next, as shown in FIG. 10E, the cavity gaps 48 are filled with the dielectric material according to the step 1006.

The first capacitor 238a includes a first conductive electrode 40a and a second conductive electrode 42a. Each of the conductive electrodes 40, 42 include an upper segment or surface coplanar with the top conductive layer 12, and a lower segment or surface coplanar with the bottom conductive layer 14. Thus, the first conductive electrode 40a is defined by the upper surface 40a-1 and the bottom surface 40a-2, while the second conductive electrode 42a is defined by the upper surface 42a-1 and the bottom surface 42a-2. The upper surface 40a-1 of the first conductive electrode 40a is spaced apart from the first top conductive layer segment 12a, and the lower surface 40a-2 of the first conductive electrode 40a is spaced apart from the second bottom conductive layer segment 14a. A left cavity gap 48a-1 separates the first substrate segment 10a from the first conductive electrode 40a. Along these lines the upper surface 42a-1 of the second conductive electrode 42a is spaced apart from the second top conductive layer segment 12b and the lower surface 42a-2 of the second conductive electrode 42a is spaced apart from the second bottom conductive layer segment 14b. A right cavity gap 48a-2 separates the second substrate segment 10b from the second conductive electrode 42a.

The second capacitor 238b includes a first conductive electrode 40b and a second conductive electrode 42b. The first conductive electrode 40b is defined in part by the upper surface 40b-1 and the bottom surface 40b-2, while the second conductive electrode 42b is defined in part by the upper surface 42b-1 and the bottom surface 42b-2. The upper surface 40b-1 of the first conductive electrode 40b is spaced apart from the second top conductive layer segment 12b, and the lower surface 40b-2 of the first conductive electrode 40b is spaced apart from the second bottom conductive layer segment 14b. A left cavity gap 48b-1 separates the second substrate segment 10b from the first conductive electrode 40b. The upper surface 42b-1 of the second conductive electrode 42b is spaced apart from the third top conductive layer segment 12c and the lower surface 42b-2 of the second conductive electrode 42b is spaced apart from the third bottom conductive layer segment 14c. A right cavity gap 48b-2 separates the third substrate segment 10c from the second conductive electrode 42b.

The third capacitor 238c includes a first conductive electrode 40c and a second conductive electrode 42c. The first conductive electrode 40c is defined in part by the upper surface 40c-1 and the bottom surface 40c-2, while the second conductive electrode 42c is defined in part by the upper surface 42c-1 and the bottom surface 42c-2. The upper surface 40c-1 of the first conductive electrode 40c is spaced apart from the third top conductive layer segment 12c, and the lower surface 40b-2 of the first conductive electrode 40b is spaced apart from the third bottom conductive layer segment 14c. A left cavity gap 48c-1 separates the third substrate segment 10c from the first conductive electrode 40c. The upper surface 42c-1 of the second conductive electrode 42c is spaced apart from the fourth top conductive layer segment 12d and the lower surface 42c-2 of the second conductive electrode 42c is spaced apart from the fourth bottom conductive layer segment 14d. A right cavity gap 48c-2 separates the fourth substrate segment 10d from the second conductive electrode 42c.

The fourth capacitor 238d includes a first conductive electrode 40d and a second conductive electrode 42d. The first conductive electrode 40d is defined in part by the upper surface 40d-1 and the bottom surface 40d-2, while the second conductive electrode 42d is defined in part by the upper surface 42d-1 and the bottom surface 42d-2. The upper surface 40d-1 of the first conductive electrode 40d is spaced apart from the fourth top conductive layer segment 12d, and the lower surface 40d-2 of the first conductive electrode 40d is spaced apart from the fourth bottom conductive layer segment 14d. A left cavity gap 48d-1 separates the fourth substrate segment 10d from the first conductive electrode 40d. The upper surface 42d-1 of the second conductive electrode 42d is spaced apart from the fifth top conductive layer segment 12e and the lower surface 42d-2 of the second conductive electrode 42d is spaced apart from the fifth bottom conductive layer segment 14e. A right cavity gap 48d-2 separates the fifth substrate segment 10e from the second conductive electrode 42d. FIG. 10F illustrates the completed passive device array 50c after step 1008 of removing the dicing tape 34 from the double-clad laminate substrate 10.

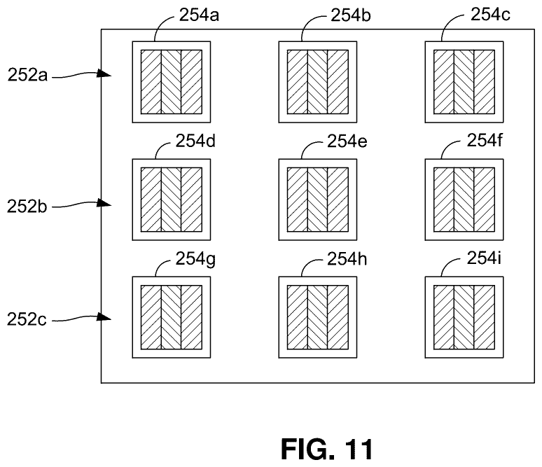

The passive device array 50c is not limited to a single row of passive devices 138. FIG. 11 is a top plan view of a 3×3 array, with a first row 252a including a first capacitor 254a, a second capacitor 254b, and a third capacitor 254c. A second row 252b includes a fourth capacitor 254d, a fifth capacitor 254e, and a sixth capacitor 254f. A third row 252c includes a seventh capacitor 254g, an eighth capacitor 254h, and a ninth capacitor 254i. The embodiments of the present disclosure contemplate the interconnection of the passive devices 138 by a downstream integrated circuit developer that tailors to the passive device array 50 a specific application.

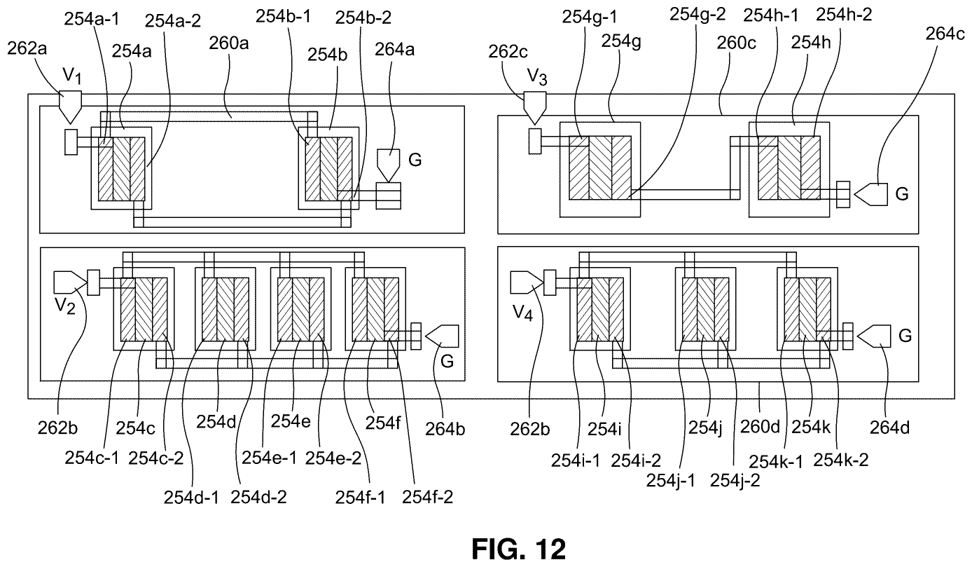

FIG. 12 illustrates the fourth embodiment of the passive device array 50d that is configured to support different voltage rails, with each voltage input and output being connectible to various capacitor modules 260, depending on system architecture and decoupling needs therefor. An exemplary first capacitor module 260a includes a first capacitor 254a, and a second capacitor 154b, as well as a first capacitor module input port 262a and a first capacitor module output port 264a. The first capacitor 254a includes a first terminal 254a-1 that is connected to the first capacitor module input port 262a and a second terminal 254a-2. The second capacitor 254b includes a first terminal 254b-1 and a second terminal 254b-2 that is connected to the first capacitor module output port 264a. The first capacitor 254a and the second capacitor 254b are connected in parallel, meaning that the first terminal 254a-1 of the first capacitor 254a is connected to the first terminal 254b-1 of the second capacitor 254b, and the second terminal 254a-2 of the first capacitor 254a is connected to the second terminal 254b-2 of the second capacitor 254b.

An exemplary second capacitor module 260b includes four capacitors: a third capacitor 254c, and a fourth capacitor 254d, a fifth capacitor 254e, and a sixth capacitor 254f. There is also a second capacitor module input port 262b and a second capacitor module output port 264b. Each of the capacitors 254 include first and second terminals, e.g., first terminal 254c-1 and second terminal 254c-2 of the third capacitor 254c, first terminal 254d-1 and second terminal 254d-2 of the fourth capacitor 254d, first terminal 254e-1 and second terminal 254e-2 of the fourth capacitor 254e, and first terminal 254f-1 and second terminal 254f-2 of the fifth capacitor 254f. The four capacitors 254c-254f are connected in parallel, so the first terminals 254c-1, 254d-1, 254e-1, and 254f-1 are connected together, and the second terminals 254c-2, 254d-2, 254e-2, and 254f-2 are connected together. The first terminal 254c-1 of the third capacitor 254c is connected to the second capacitor module input port 262b, while the second terminal 254f-2 of the sixth capacitor 254f is connected to the second capacitor module output port 264b.

An exemplary third capacitor module 260c includes a seventh capacitor 254g, and an eighth capacitor 254h, as well as a third capacitor module input port 262c and a third capacitor module output port 264c. The seventh capacitor 254g includes a first terminal 254g-1 that is connected to the third capacitor module input port 262c and a second terminal 254g-2. The eighth capacitor 254h includes a first terminal 254h-1 and a second terminal 254h-2 that is connected to the third capacitor module output port 264c. The seventh capacitor 254g and the eighth capacitor 254h are connected in series, meaning that the second terminal 254g-2 of the seventh capacitor 254g is connected to the first terminal 254h-1 of the eighth capacitor 254h. The second terminal 254h-2 of the eighth capacitor 254h is connected to the third capacitor module output port 264c.

An exemplary fourth capacitor module 260d includes three capacitors: a ninth capacitor 254i, and a tenth capacitor 254j, and an eleventh capacitor 254k. There is a fourth capacitor module input port 262d and a fourth capacitor module output port 264d. Each of the capacitors 254 includes first and second terminals, e.g., first terminal 254i-1 and second terminal 254l-2 of the ninth capacitor 254i, first terminal 254j-1 and second terminal 254j-2 of the tenth capacitor 254j, and first terminal 254k-1 and second terminal 254k-2 of the eleventh capacitor 254k. The three capacitors 254i-254k are connected in parallel, so the first terminals 254i-1, 254j-1, and 254k-1 are connected together, and the second terminals 254i-2, 254j-2, and 254k-2 are connected together. The first terminal 254i-1 of the ninth capacitor 254i is connected to the fourth capacitor module input port 262d, while the second terminal 254k-2 of the eleventh capacitor 254k is connected to the fourth capacitor module output port 264d.

Each of the interconnections of the capacitors 254 in the capacitor modules 260a-260d are presented by way of example only and not of limitation. Each capacitor module 260 may be configured according to the specifics of the application and are not limited to that which is shown and described above. Again, each of the capacitor modules 260 is understood to correspond to a specific voltage rail. The properties and architecture of each of the capacitor modules 260 may be identical or different from one another, as illustrated. The aforementioned connections are understood to be defined through RDLs.

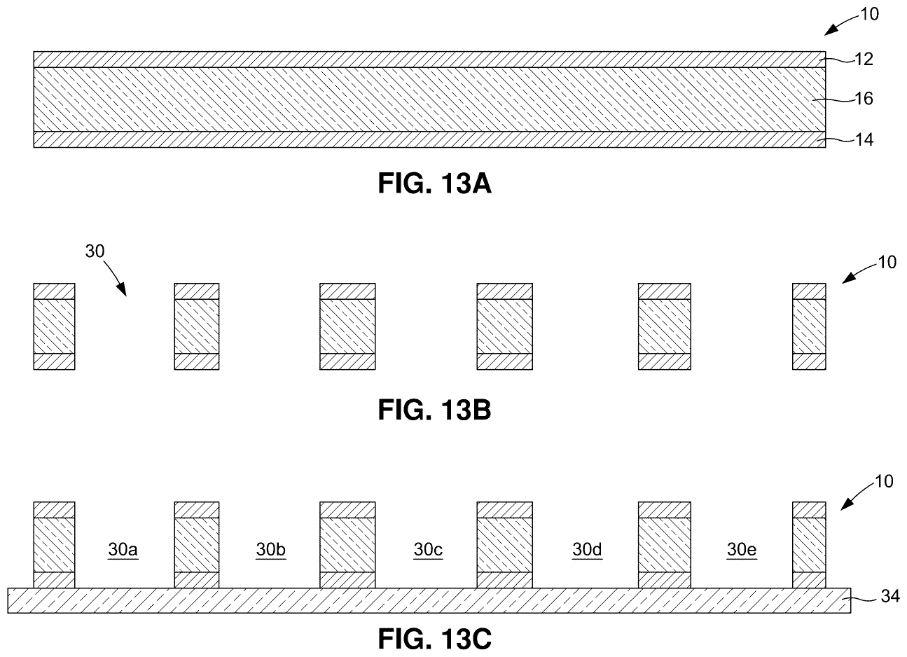

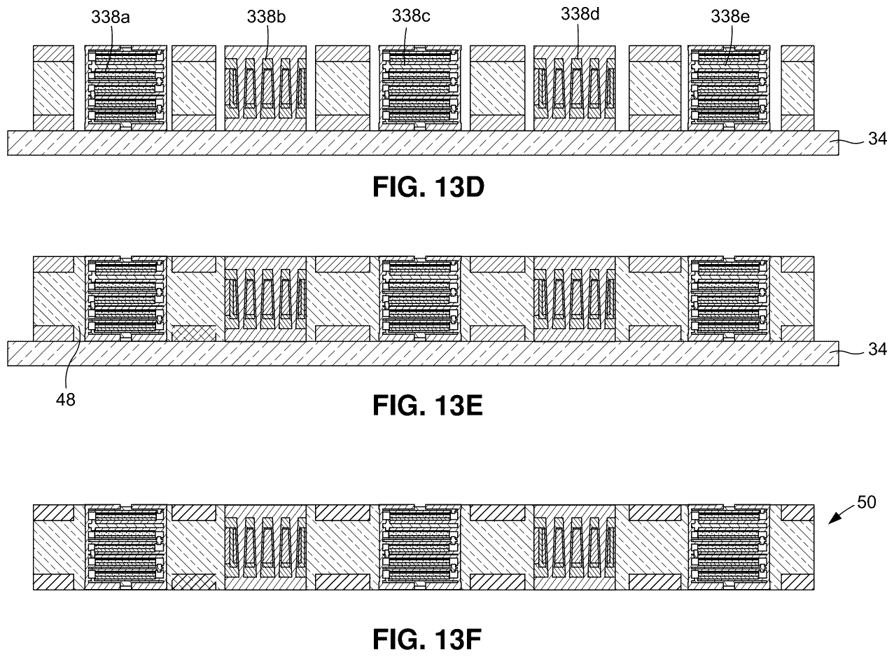

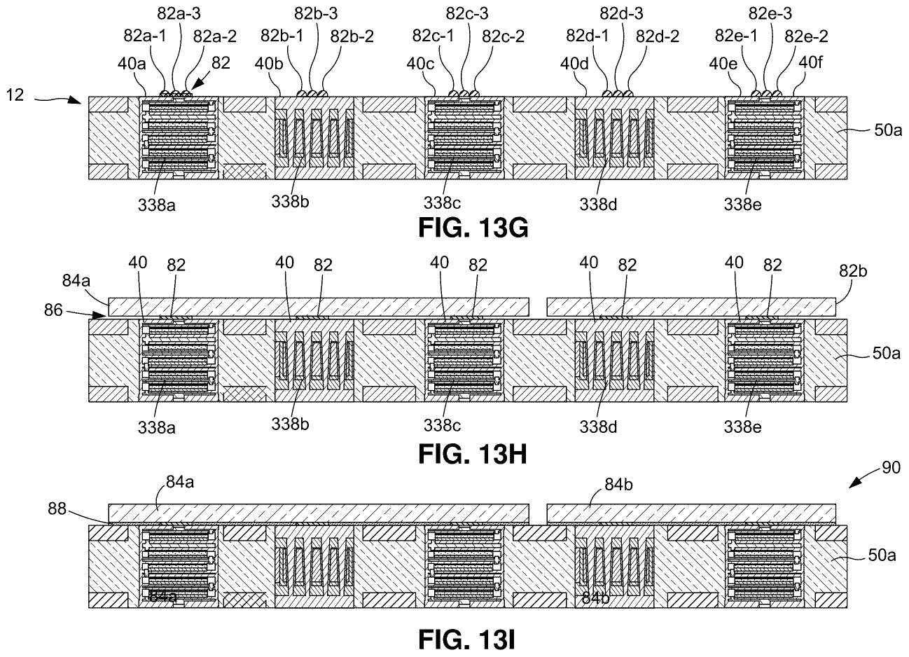

Another embodiment of the present disclosure contemplates the placement of an active device on top of the passive device array 50a. The active device may be a power management integrated circuit (PMIC) to which capacitors, inductors, and LC (inductor-capacitor) circuits may be connected. The initial steps of the fabrication process is the same as described above in connection with the first embodiment of the passive device array 50a, as shown in the cross-sectional views of FIGS. 13A-13F. Specifically, FIG. 13A shows the same double-clad laminate substrate 10 defined by the top conductive layer 12, the bottom conductive layer 14, and the dielectric layer 16 between the top conductive layer 12 and the bottom conductive layer 14. As in the first embodiments, the method begins with the step 1000 of forming the cavities 30 in the double-clad laminate substrate 10 as shown in FIG. 13B. The dicing tape 34 is then laminated onto the double-clad laminate substrate 10 in accordance with the step 1002 and shown in FIG. 13C. FIG. 13D shows the next step 1004 of placing the passive devices 338 into the respective cavities 30. In further detail, a first capacitor 338a is placed in the first cavity 30a, a first inductor 338b is placed in the second cavity 30b, a second capacitor 338c is placed in the third cavity 30c, a second inductor 338d is placed in the fourth cavity 30d, and a third capacitor 338e is placed in a fifth cavity 30e. Next, as shown in FIG. 13E, the cavity gaps 48 are filled with the dielectric material in accordance with the step 1006. Following this step, as shown in FIG. 13F, the dicing tape 34 is removed from the double-clad laminate substrate 10. The details of the passive devices 338, the double-clad laminate substrate 10, and the constituent structural elements thereof are essentially the same as for the first embodiment of the passive device array 50a and will not be repeated.

Referring back to the flowchart of FIG. 1, and as shown in FIG. 13G, the fabrication of an active device stack with the passive device array 50a then proceeds to a step 2000 of placing one or more electrical interconnects 82 on the conductive electrodes 40, 42 of the passive devices 338. The first capacitor 338a has a first conductive electrode 40a and a second conductive electrode 42b that is coplanar with the top conductive layer 12, the first inductor 338b has a first conductive electrode 40b that is coplanar with the top conductive layer 12, the second capacitor 338c has a first conductive electrode 40c and a second conductive electrode 42c that is coplanar with the top conductive layer 12, the second inductor 338d has a first conductive electrode 40d that is coplanar with the top conductive layer 12, and the third capacitor 338e has a first conductive electrode 40e and a second conductive electrode 42e that is coplanar with the top conductive layer 12.

It is on these surfaces that the electrical interconnects 82 are placed. In one exemplary embodiment, the electrical interconnect 82 is a micro ball grid array (BGA) ball that is electrically conductive and ductile at a predetermined temperature to form an electrical-mechanical bond to a corresponding pad on an active device. A first electrical interconnect 82a-1 is placed on the first conductive electrode 40a of the first capacitor 338a, a second electrical interconnect 82a-2 is placed on the second conductive electrode 42a of the first capacitor 338a, and a third electrical interconnect 82a-3 is placed in between the first and second electrical interconnects 82a-1, 82a-2. Three electrical interconnects 82b-1, 82b-2, and 82b-3 are placed in a central region of the first conductive electrode 40b of the first inductor 338b. Similar to the first capacitor 338a, a first electrical interconnect 82c-1 is placed on the first conductive electrode 40c of the second capacitor 338c, a second electrical interconnect 82c-2 is placed on the second conductive electrode 42c of the second capacitor 338c, and a third electrical interconnect 82c-3 is placed between the first electrical interconnect 82c-1 and the second electrical interconnect 82c-2. As with the first inductor 338b, three electrical interconnects 82d-1, 82d-2, and 82d-3 are placed in a central region of the first conductive electrode 40d of the second inductor 338d. Like the first capacitor 338a and the second capacitor 338c, a first electrical interconnect 82e-1 is placed on the first conductive electrode 40e of the third capacitor 338e, a second electrical interconnect 82e-2 is placed on the second conductive electrode 42e of the third capacitor 338e, and a third electrical interconnect 82e-3 is placed between the first electrical interconnect 82e-1 and the second electrical interconnect 82e-2.

As shown in FIG. 13H, the fabrication process continues with a step 2002 of establishing connections of conductive terminals on active devices 84a, 84b. This includes placing the first active device 84a and the second active device 84b onto the passive device array 50a, such that the conductive pads are in alignment with the electrical interconnects 82. As noted above, the active device 84 may be a power management integrated circuit (PMIC), though other active integrated circuit devices fabricated using Gallium Nitride (GaN), Silicon Carbide (SiC), or any other suitable semiconductor technology may be substituted without departing from the scope of the present disclosure. According to the illustrated example, the first active device 84a is connected to the first capacitor 388a, the first inductor 338b, and the second capacitor 338c, while the second active device 84b is connected to the second inductor 338d and the third capacitor 338e, though this is by way of example only.

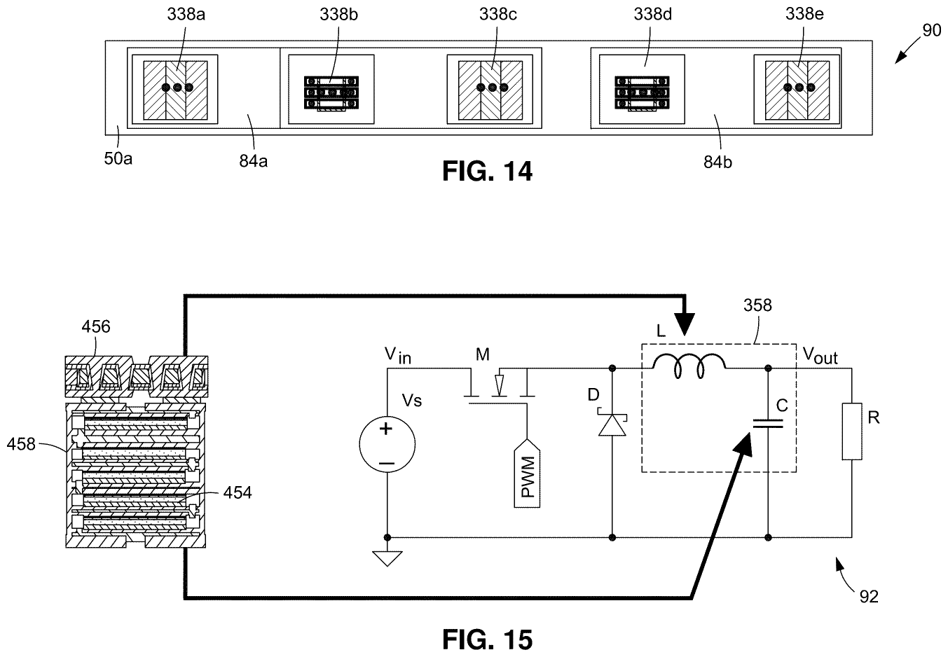

Once the active devices 84, 84b are placed onto the passive device array 50a, the entire assembly may be brought to the predefined temperature in a reflow oven such that the solder balls/electrical interconnects 82 melt and establish the electrical/mechanical connection with the conductive terminals and the conductive electrodes 40. After the solder balls/electrical interconnects 82 cool, the method may proceed to a step 2004 of underfilling a space 86 between a bottom surface of the active devices 84 and a top surface of the passive device array 50a. FIG. 13I depicts such underfill layer 88. FIG. 14 shows the top view of the completed active device and passive array stack 90, including the passive device array 50a with the passive devices 338a-338e, and the active devices 84a, 84b. This configuration is envisioned to reduce the overall footprint of the power management IC, while providing the necessary input and output passive components, e.g., capacitors, inductors, and LC circuits.

Various embodiments of a passive device array 50 in which one passive device 38 occupies the entire vertical height of the double-clad laminate substrate 10 have been disclosed. According to other embodiments, there may be more than one passive device stacked onto another within the same depth of the cavity formed in the substrate 10. In one case, an inductor and a capacitor may be stacked and connected in series, which may be referred to as an LC circuit. Referring to the circuit diagram of FIG. 15, one possible application for such an LC circuit 458 is in a DC-DC buck converter 92. As will be recognized by those having ordinary skill in the art, the buck converter 92 has an input of a higher DC voltage, which is passed to a transistor M. There is a diode D connected across the transistor, and the base/gate of the transistor M is provided with a steady pulse-width modulation signal. Additionally, there is an LC circuit 458, with the junction between the inductor L and the capacitor C being the output Vout. The buck converter 92 reduces the voltage to a predetermined level while increasing the current and are thus used in a wide range of electronic circuits where a high supply voltage is reduced to a lower level, e.g., a digital logic high of 5V, 3.3V, 1.8V, etc.

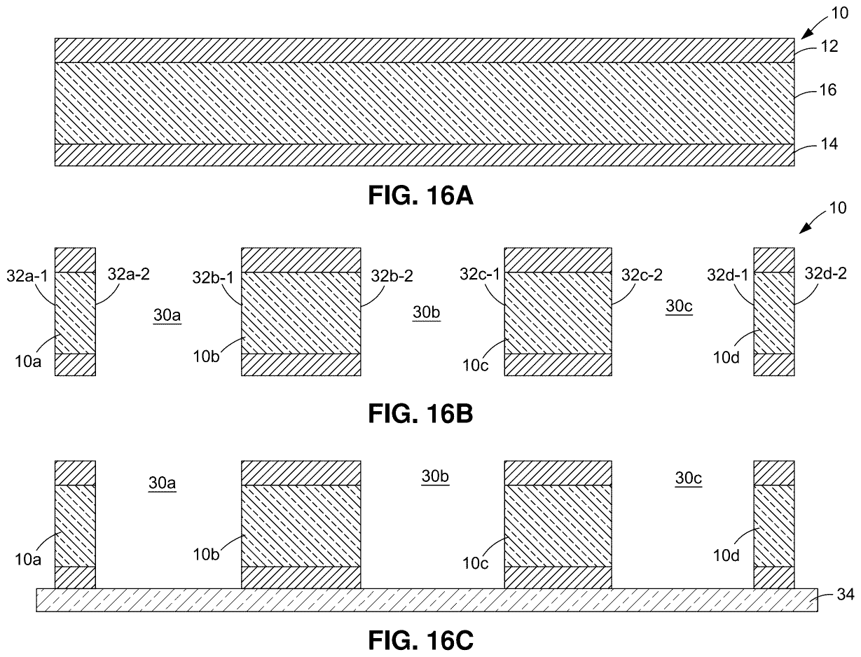

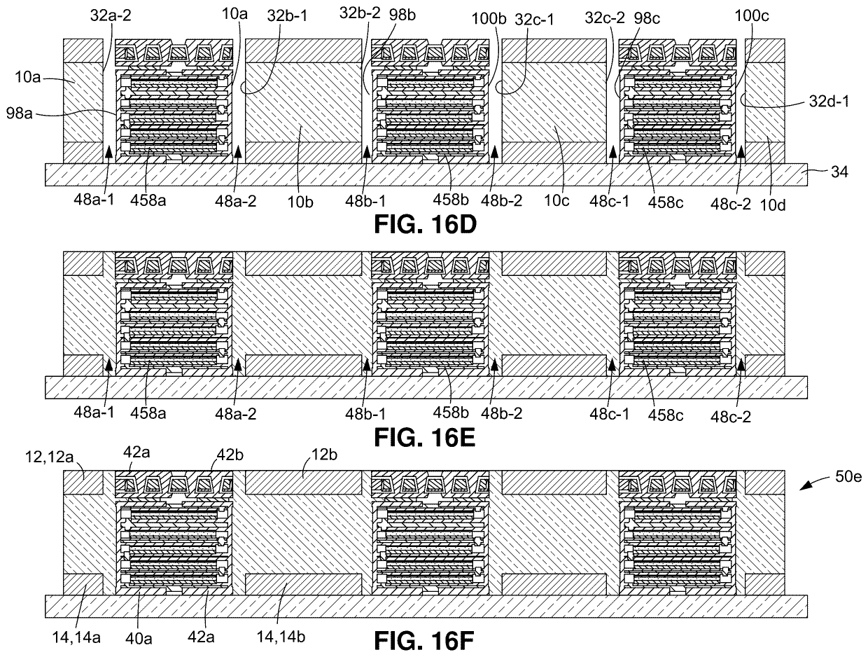

FIGS. 16A-16F depict the fabrication of a fifth embodiment of the passive device array 50e that includes the inductor-capacitor (LC) circuit 458. In further detail shown in FIG. 16A, the double-clad laminate substrate 10 is defined by the top conductive layer 12, the bottom conductive layer 14, and the dielectric layer 16 between the top conductive layer 12 and the bottom conductive layer 14. As in the previously described embodiments, the method begins with the step 1000 of forming the cavities 30 in the double-clad laminate substrate 10 as shown in FIG. 16B. In this example, there is a first cavity 30a, a second cavity 30b, and a third cavity 30c.

With the cavities 30 formed, the substrate 10 may be separated into the first substrate segment 10a, the second substrate segment 10b, the third substrate segment 10c, and the fourth substrate segment 10d. The first substrate segment 10a has the left sidewall 32a-1 and a right sidewall 32a-2. The second substrate segment 10b likewise has a left sidewall 32b-1 and a right sidewall 32b-2. The first cavity 30a is bounded by the right sidewall 32a-2 of the first substrate segment 10a and the left sidewall 32b-1 of the second substrate segment 10b. The third substrate segment 10c is defined by a left sidewall 32c-1 and a right sidewall 32c-2, with the left sidewall 32c-1 and the right sidewall 32b-2 of the second substrate segment 10b defining the boundaries of the second cavity 30b. Similarly, the fourth substrate segment 10d is defined by a left sidewall 32d-1 and a right sidewall 32d-2. The third cavity 30c is bounded by the left sidewall 32d-1 of the fourth substrate segment 10d and the right sidewall 32c-2 of the third substrate segment 10c.

The dicing tape 34 is then laminated onto the double-clad laminate substrate 10 in accordance with the step 1002 and shown in FIG. 16C. Next, FIG. 16D shows the step 1004 of placing the LC circuit 458 into the respective cavities 30. In further detail, a first LC circuit 458a is placed in the first cavity 30a, a second LC circuit 458b is placed in the second cavity 30b, and a third LC circuit 458c is placed in the third cavity 30c. Because the LC circuits 458 of different component (capacitance and inductance) values can be interchangeably placed within the double-clad laminate substrate 10, they may also be referred to as LC tiles.

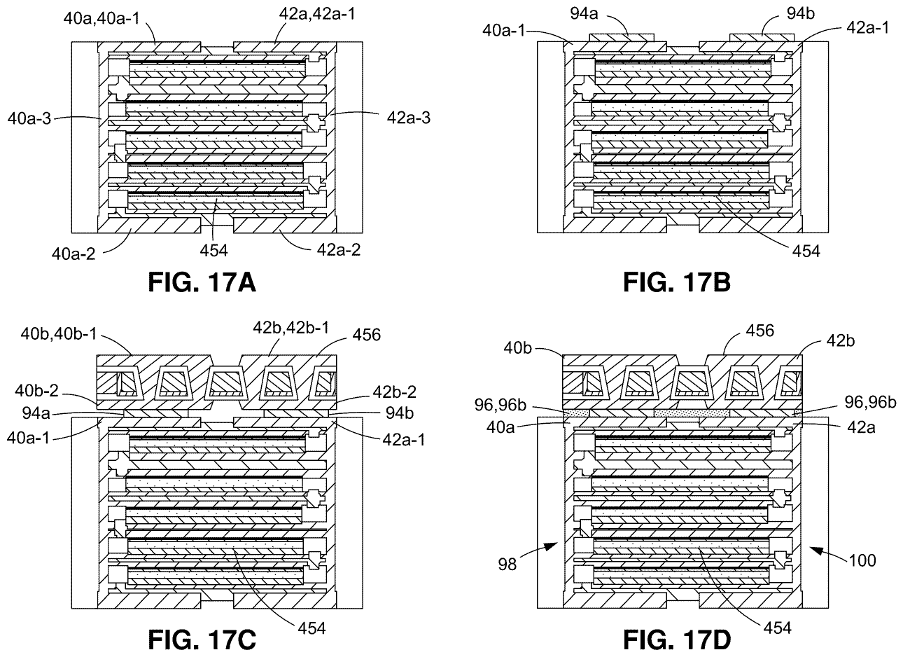

Now referring to FIGS. 17A-17D, the LC circuit 458 includes the capacitor 454. Although the capacitor 454 may have a variety of internal configurations of dielectrics, anodes, and cathodes, externally accessible features include the first conductive electrode 40 and the second conductive electrode 42. In the illustrated embodiment, the anode may be fabricated from aluminum with an oxide layer formed thereon serving as the dielectric. However, any other suitable capacitor configuration may be substituted. The first conductive electrode 40a is characterized by a top segment 40a-1, a bottom segment 40a-2, and a vertical connecting segment 40a-3 that ties the top segment 40a-1 to the bottom segment 40a-2. Similarly, the second conductive electrode 42a is characterized by a top segment 42a-1, a bottom segment 42a-2, and a vertical connecting segment 42a-3. FIG. 17A in particular shows the capacitor 454 in its standalone configuration.

FIG. 17B next illustrates the application of a conductive paste 94 onto the top segments 40a-1, 42a-1 of the first conductive electrode 40a and second conductive electrode 42a, respectively. Specifically, a first layer of conductive paste 94a is applied to the top segment 40a-1 of the first conductive electrode 40a, and a second layer of conductive paste 94b is applied to the top segment 42a-1 of the second conductive electrode 42a. The conductive paste 94 may be applied via a screen printing method or any other suitable method.

The LC circuit 458 also includes the inductor 456, and FIG. 17C illustrates the inductor 456 placed onto the capacitor 454. The inductor 456 similarly includes a first conductive electrode 40b, with a top segment 40b-1 and a bottom segment 40b-2. Additionally, there is a second conductive electrode 42b also with a top segment 42b-1 and a bottom segment 42b-2. The bottom segment 40b-2 of the inductor first conductive electrode 40b is connected to the top segment 40a-1 of the capacitor first conductive electrode 40a with the first layer of conductive paste 94a, and the bottom segment 42b-2 of the inductor second conductive electrode 42b is connected to the top segment 42a-1 of the capacitor second conductive electrode 42a. Next, FIG. 17D illustrates an underfill 96 within the space between the first conductive electrode 40a of the capacitor 454 and the first conductive electrode 40b of the inductor 40b, and between the second conductive electrode 42a of the capacitor 454 and the second conductive electrode 42b of the inductor 456. Combined, the LC circuit 458 is defined by a left sidewall 98 and a right sidewall 100.

Referring back to FIG. 16D, once the LC circuits 458 are placed within the cavities 30, there are cavity gaps 48 defined between each sidewall of the LC circuits 458 and adjacent sidewalls 32 of the substrate segments 10a-10d. Specifically, the left sidewall 98a of the first LC circuit 458a is separated from the right sidewall 32a-2 of the first substrate segment 10a by a left cavity gap 48a-1, while the opposite right sidewall 100a of the first LC circuit 458a is separated from the right sidewall 32b-1 of the second substrate segment 10b by a right cavity gap 48a-2. The left sidewall 98b of the second LC circuit 458b is separated from the right sidewall 32b-2 of the second substrate segment 10b by a left cavity gap 48b-1, and the right sidewall 100b of the second LC circuit 458b is separated from the left sidewall 32c-1 of the third substrate segment 10c by a right cavity gap 48b-2. The left sidewall 98c of the third LC circuit 458c is separated from the right sidewall 32c-2 of the third substrate segment 10c by a left cavity gap 48c-1, and the right sidewall 100c of the third LC circuit 458c is separated from the left sidewall 32d-1 of the third substrate segment 10c by a right cavity gap 48c-2. The LC circuits 458 are mounted to the adhesive on the dicing tape 34. Next, according to the step 1006, the cavity gaps 48 are filled with a dielectric material, then in step 1008, the dicing tape 34 is removed, leaving the passive device array 50e with the vertically stacked LC circuit 458.

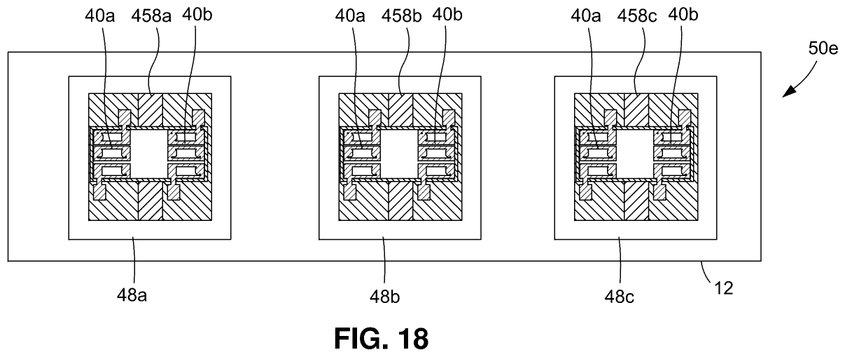

The LC circuits 458 have substantially the same thickness as the substrate 10 overall, such that the conductive electrodes 40b, 42b of the inductor 456 are coplanar with the top conductive layer 12, and the conductive electrodes 40a, 42a of the capacitor 454 are coplanar with the bottom conductive layer 14. As illustrated in FIG. 18, the uppermost surface of the LC circuit 458, e.g., the conductive electrodes 40b, 42b of the inductor 456, are exposed, as is the top conductive layer 12. The cavity gaps 48a-48c surround the respective one of the LC circuits 458a-458c. Although not shown in FIG. 18, FIG. 16F shows that the bottommost surface of the LC circuit 458, e.g., the conductive electrodes 40a, 40b of the capacitor 454, are also exposed.

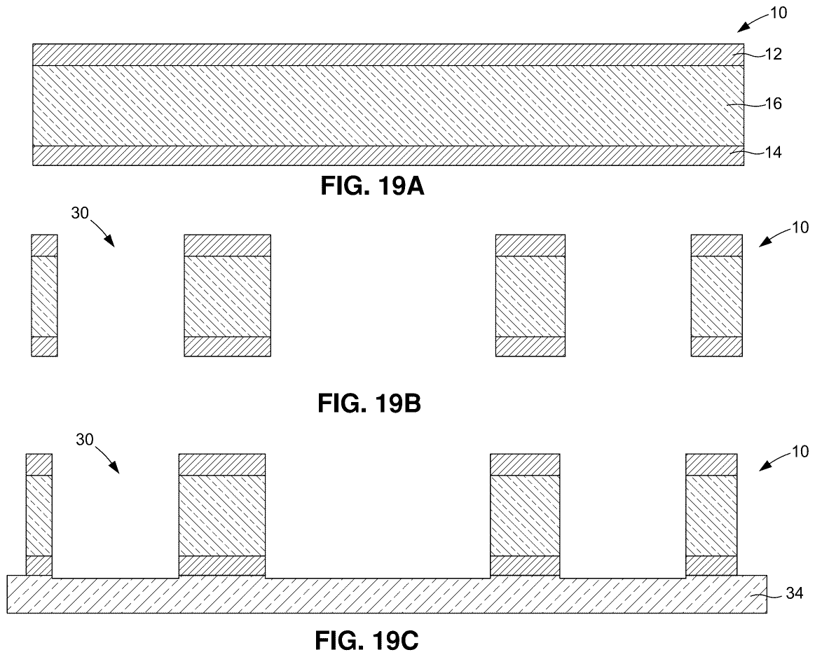

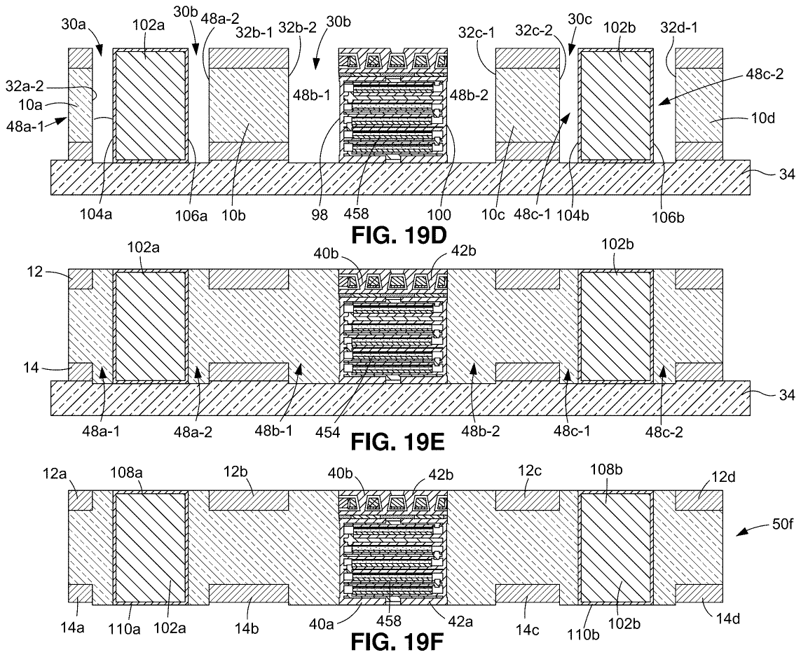

The LC circuit 458 may generate substantial heat within the double-clad laminate substrate 10, so according to another embodiment of the present disclosure, the thermal conduction blocks may be placed within one or more surrounding cavities 30 and in proximity to the LC circuit 458. FIG. 19A-19F illustrate the components of a sixth embodiment of a passive device array 50f at various stages of completion, with FIG. 19A showing the same double-clad laminate substrate 10 defined by the top conductive layer 12, the bottom conductive layer 14, and the dielectric layer 16 between the top conductive layer 12 and the bottom conductive layer 14. As in the previously described embodiments, the method begins with the step 1000 of forming the cavities 30 in the double-clad laminate substrate 10, which is best illustrated in FIG. 19B. FIG. 19C then shows the dicing tape 34 laminated onto the double-clad laminate substrate 10 in accordance with the step 1002.

FIG. 19D shows the next step 1004 of placing the passive device/LC circuit 458 into the second cavity 30b. In this embodiment, there is an additional step that is not included in the earlier described embodiments, that is, step 1100 of placing a thermal conduction block 102 in the cavity and attaching the same to the dicing tape 34. In particular, a first thermal conduction block 102a is placed in the first cavity 30a, and a second thermal conduction block 102b is placed in the third cavity 30c. The thermal conduction block 102 is understood to be an aluminum block, and is contemplated to help dissipate lateral heat that is generated by the adjacent LC circuit 458. Similar to the passive devices placed within the cavity 30, the thermal conduction blocks 102a, 102b are each defined by left sidewall 104a, 104b, respectively, and a right sidewall 106a, 106b, respectively.

The left sidewall 104a of the first thermal conduction block 102a is separated from the right sidewall 32a-2 of the first substrate segment 10a by a left cavity gap 48a-1, and the opposite right sidewall 106a of the first thermal conduction block 102a is separated from the right sidewall 32b-1 of the second substrate segment 10b by a right cavity gap 48a-2. The left sidewall 98 of the LC circuit 458 is separated from the right sidewall 32b-2 of the second substrate segment 10b by a left cavity gap 48b-1, and the right sidewall 100 of the LC circuit 458 is separated from the left sidewall 32c-1 of the third substrate segment 10c by a right cavity gap 48b-2. The left sidewall 104b of the second thermal conduction block 102b is separated from the right sidewall 32c-2 of the third substrate segment 10c by a left cavity gap 48c-1, and the right sidewall 106b of the second thermal conduction block 102b is separated from the left sidewall 32d-1 of the third substrate segment 10c by a right cavity gap 48c-2.

The LC circuit 458 and the thermal conduction blocks 102 are mounted to the adhesive on the dicing tape 34. Next, according to step 1006, the cavity gaps 48 are filled with a dielectric material, then in step 1008, the dicing tape 34 is removed, leaving the passive device array 50f with the vertically stacked LC circuit 458 and the thermal conduction blocks 102.

The thermal conduction blocks 102a, 102b have substantially the same thickness as the substrate 10 overall, such that the top surfaces 108a, 108b are coplanar with the top conductive layer 12 as well as the uppermost surface of the LC circuit 458, e.g., the conductive electrodes 40b, 42b of the inductor 456. Additionally, the bottom surfaces 110a, 110b are coplanar with the bottom conductive layer 14 and the bottommost surface of the LC circuit 458, e.g., the conductive electrodes 40a, 42a of the capacitor 454.

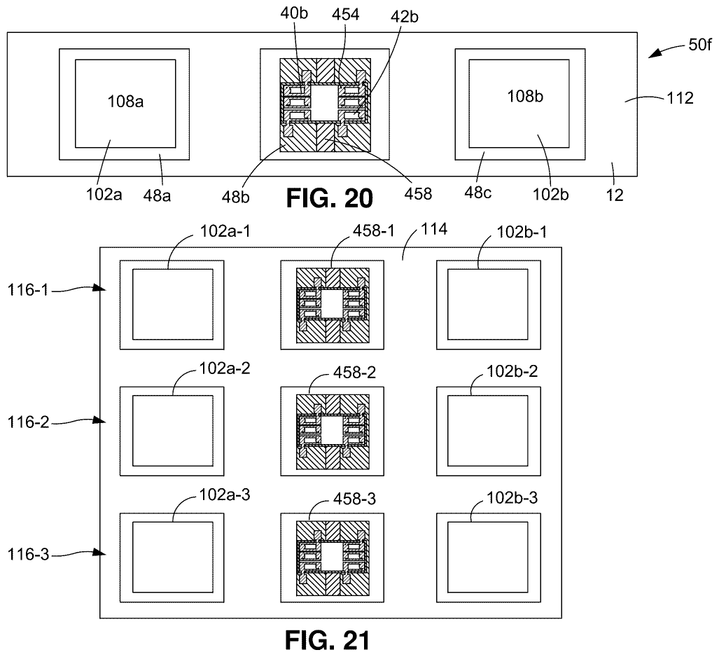

FIG. 20 illustrates a single row array structure 112 comprised of the thermal conduction blocks 102 and the LC circuit 458, showing the uppermost surfaces thereof, e.g., top surface 108a and 108b of the first and second thermal conduction blocks 102a, 102b, respectively, and the conductive electrodes 40b, 42b of the inductor 456 that is a part of the LC circuit 458. The first cavity gap 48a surrounds the first thermal conduction block 102a, the second cavity gap 48b surrounds the LC circuit 458, and the third cavity gap 48c surrounds the second thermal conduction block 102b.

A single row array is not the only structure possible, with FIG. 21 illustrating a 3×3 matrix structure 114 comprised of multiple repeating rows 116 of the single row array structure 112. In a first row 116-1, there is a first thermal conduction block 102a-1, an LC circuit 458-1, and a second thermal conduction block 102b-1. In a second row 116-2, there is a first thermal conduction block 102b-1, another LC circuit 458-2, and a second thermal conduction block 102b-2. In a third row 116-3, there is a first thermal conduction block 102c-1, an LC circuit 458-3, and a second thermal conduction block 102c-2.

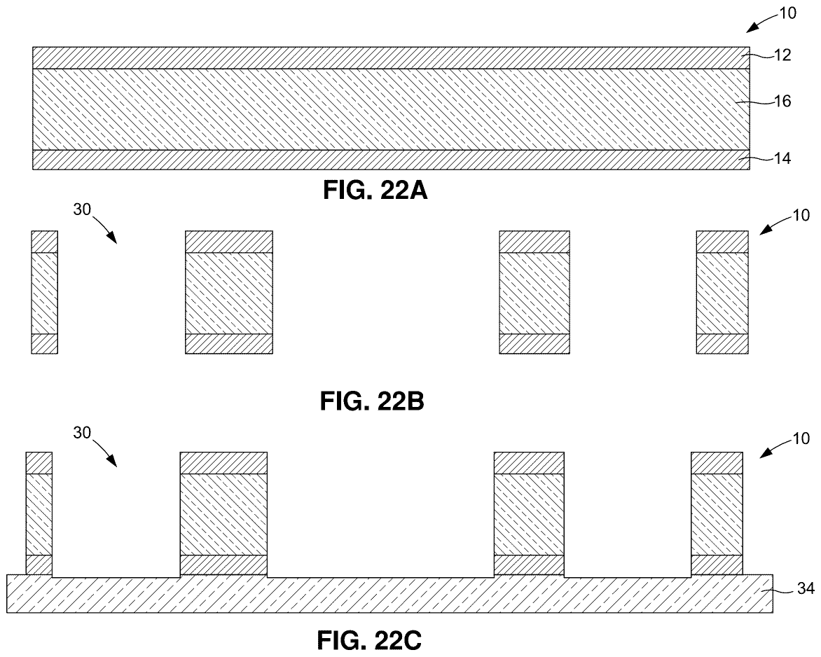

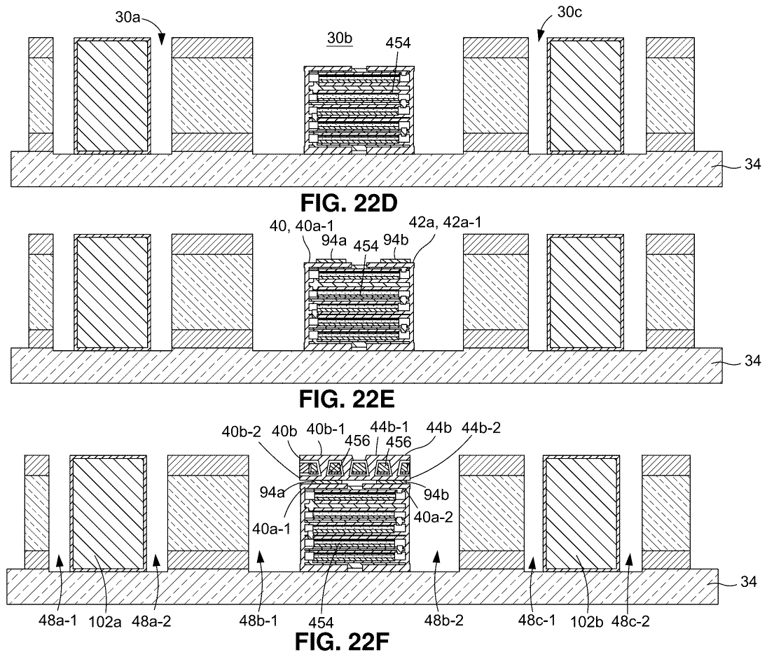

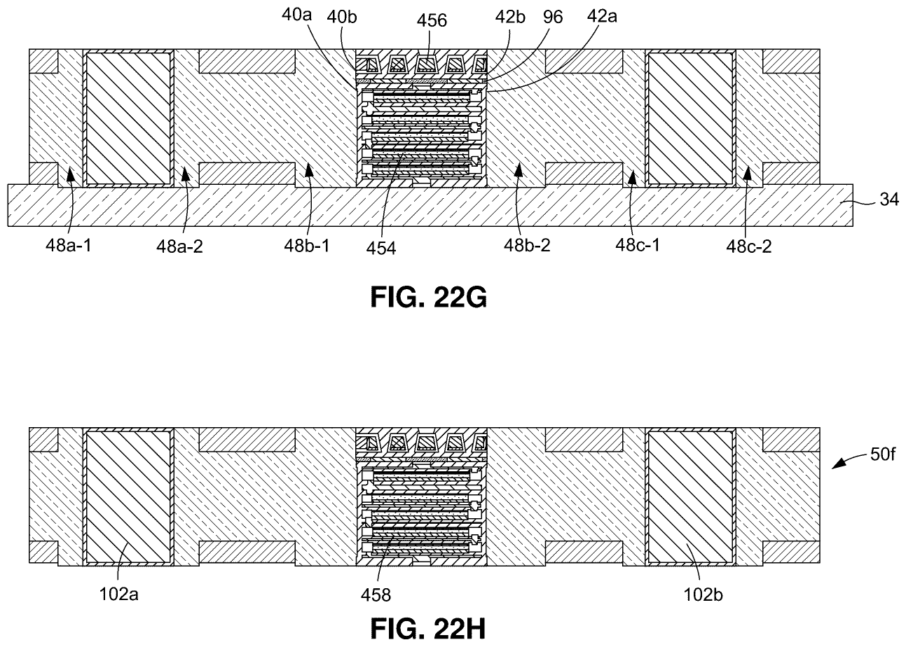

The process for fabricating the sixth embodiment of the passive device array 50f described above involved the placement of a pre-fabricated LC circuit 458 into the cavity 30. Alternatively, it is possible to fabricate the LC circuit 458 within the cavity 30 alongside the placement of the other components, namely, the thermal conduction blocks 102. FIG. 22A-22H illustrate the components of the sixth embodiment of a passive device array 50f at various stages of completion in accordance with this alternative fabrication process, with FIG. 22A showing the same double-clad laminate substrate 10 defined by the top conductive layer 12, the bottom conductive layer 14, and the dielectric layer 16 between the top conductive layer 12 and the bottom conductive layer 14. With additional reference to FIG. 22B, the method begins with the step 1000 of forming the cavities 30 in the double-clad laminate substrate 10. FIG. 22C then shows the dicing tape 34 laminated onto the double-clad laminate substrate 10 in accordance with the step 1002.

FIG. 22D shows the next step 1004 of placing the passive device into the second cavity 30b. In particular, the passive device is the capacitor 454 of the LC circuit 458. Also shown is the result of step 1100 of placing the thermal conduction block 102 in the cavity. Specifically, the first thermal conduction block 102a is placed in the first cavity 30a, and the second thermal conduction block 102b is placed in the third cavity 30c.

The following steps of fabricating the LC circuit 458 are essentially the same as described above in the context of a separate or independent fabrication. As shown in FIG. 22E, the conductive paste 94 is applied onto the top segments 40a-1, 42a-1 of the first conductive electrode 40a and second conductive electrode 42a, respectively. The conductive paste 94 may be applied via a screen printing method or any other suitable method.

The LC circuit 458 also includes the inductor 456, and FIG. 22F illustrates the inductor 456 placed onto the capacitor 454. The inductor 456 similarly includes a first conductive electrode 40b, with a top segment 40b-1 and a bottom segment 40b-2. Additionally, there is a second conductive electrode 42b also with a top segment 42b-1 and a bottom segment 42b-2. The bottom segment 40b-2 of the inductor first conductive electrode 40b is connected to the top segment 40a-1 of the capacitor first conductive electrode 40a with the first layer of conductive paste 94a, and the bottom segment 42b-2 of the inductor second conductive electrode 42b is connected to the top segment 42a-1 of the capacitor second conductive electrode 42a. This establishes the electrical connection between the first passive device and the second passive device, that is, the inductor 456 and the capacitor 454, with such connection being either in series or in parallel.

Next, FIG. 22G illustrates an underfill 96 within the space between the first conductive electrode 40a of the capacitor 454 and the first conductive electrode 40b of the inductor 40b, and between the second conductive electrode 42a of the capacitor 454 and the second conductive electrode 42b of the inductor 456.

The LC circuit 458 and the thermal conduction blocks 102 are mounted to the adhesive on the dicing tape 34. Thereafter, according to step 1006 and as depicted in FIG. 22G, the cavity gaps 48 are filled with a dielectric material, then in step 1008 as illustrated in FIG. 22H, the dicing tape 34 is removed, leaving the passive device array 50f with the vertically stacked LC circuit 458 and the thermal conduction blocks 102.

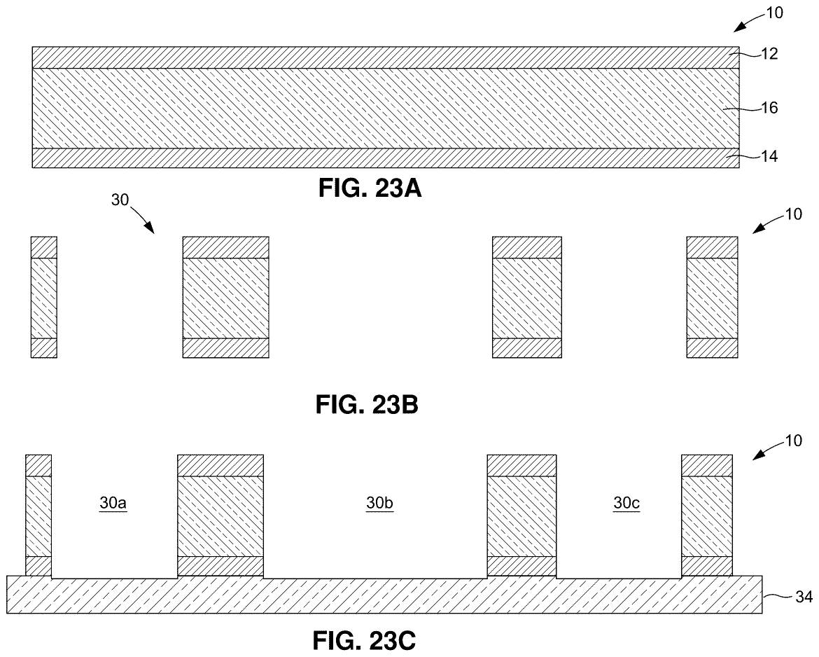

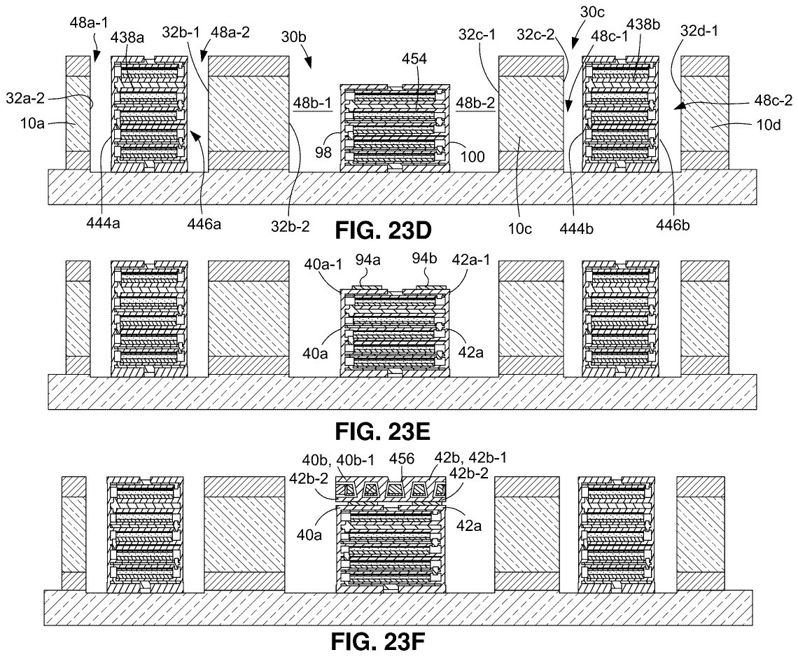

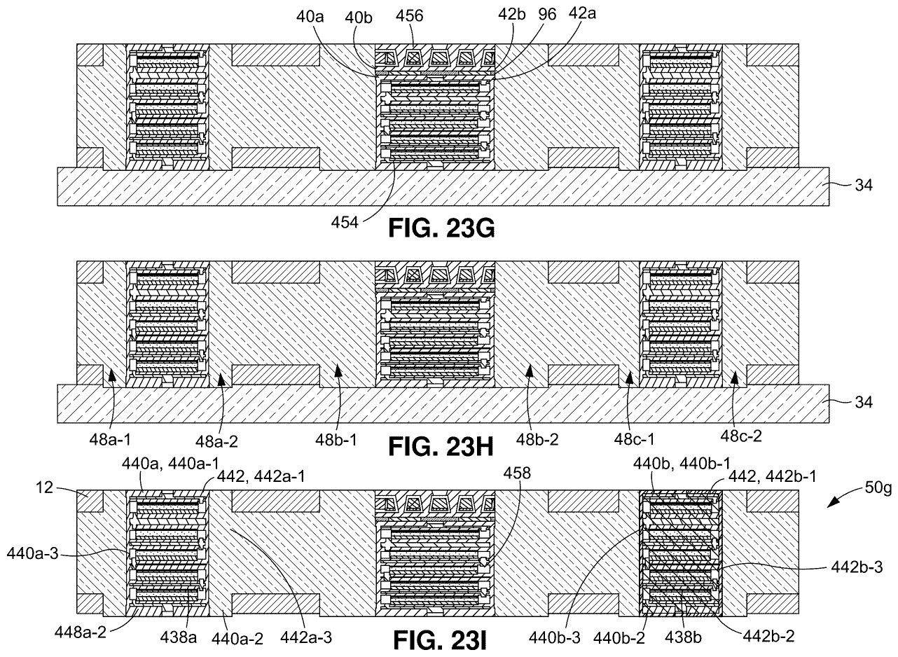

The foregoing alternative fabrication process in which the LC circuit 458 is fabricated in situ within the substrate 10 may substitute capacitors for the thermal conduction blocks 102, the details of which are shown in the FIGS. 23A-23I. Again, FIG. 23A shows the same double-clad laminate substrate 10 defined by the top conductive layer 12, the bottom conductive layer 14, and the dielectric layer 16 between the top conductive layer 12 and the bottom conductive layer 14. As shown in FIG. 22B and the flowchart of FIG. 1, the method begins with the step 1000 of forming the cavities 30 in the double-clad laminate substrate 10. FIG. 23C then shows the dicing tape 34 laminated onto the double-clad laminate substrate 10 in accordance with the step 1002.

FIG. 22D shows the next step 1004 of placing the passive devices into the cavities 30. One of the passive devices is the first capacitor 438a that is placed in the first cavity 30a and attached to the dicing tape 34. Another one of the passive devices is the capacitor 454 of the LC circuit 458. A second capacitor 438b is placed in the third cavity 30c and attached to the dicing tape 34. The first capacitor 438a is defined by a left sidewall 444a and a right sidewall 446a, while the second capacitor 438b is defined by a left sidewall 444b and a right sidewall 446b.

The left sidewall 444a of the first capacitor 438a is separated from the right sidewall 32a-2 of the first substrate segment 10a by a left cavity gap 48a-1, and the opposite right sidewall 446a of the first capacitor 438a is separated from the right sidewall 32b-1 of the second substrate segment 10b by a right cavity gap 48a-2. The left sidewall 98 of the LC circuit 458 is separated from the right sidewall 32b-2 of the second substrate segment 10b by a left cavity gap 48b-1, and the right sidewall 100 of the LC circuit 458 is separated from the left sidewall 32c-1 of the third substrate segment 10c by a right cavity gap 48b-2. As can be seen in FIG. 23D, the LC circuit 458 has not yet been fully fabricated, so the left sidewall 98 and right sidewall 100 are those of the capacitor 454. It will be shown below that the additional inductor will have a similar footprint and may thus define a portion of the left sidewall 98 and the right sidewall 100. The left sidewall 444b of the second capacitor 438b is separated from the right sidewall 32c-2 of the third substrate segment 10c by a left cavity gap 48c-1, and the right sidewall 446b of the second capacitor 438b is separated from the left sidewall 32d-1 of the third substrate segment 10c by a right cavity gap 48c-2.

The following steps of fabricating the LC circuit 458 are essentially the same as described above in the context of the sixth embodiment of the passive device array 50f and the alternative fabrication process where the LC circuit 458 is built inside the cavity 30 rather than being pre-fabricated before placement. As shown in FIG. 23E, the conductive paste 94 is applied onto the top segments 40a-1, 42a-1 of the first conductive electrode 40a and second conductive electrode 42a, respectively.

The LC circuit 458 also includes the inductor 456, and FIG. 23F illustrates the inductor 456 placed onto the capacitor 454. The inductor 456 similarly includes a first conductive electrode 40b, with a top segment 40b-1 and a bottom segment 40b-2. Additionally, there is a second conductive electrode 42b also with a top segment 42b-1 and a bottom segment 42b-2. The bottom segment 40b-2 of the inductor first conductive electrode 40b is connected to the top segment 40a-1 of the capacitor first conductive electrode 40a with the first layer of conductive paste 94a, and the bottom segment 42b-2 of the inductor second conductive electrode 42b is connected to the top segment 42a-1 of the capacitor second conductive electrode 42a. This establishes the electrical connection between the first passive device and the second passive device, that is, the inductor 456 and the capacitor 454, with such connection being either in series or in parallel.

FIG. 23G illustrates the underfill 96 within the space between the first conductive electrode 40a of the capacitor 454 and the first conductive electrode 40b of the inductor 40b, and between the second conductive electrode 42a of the capacitor 454 and the second conductive electrode 42b of the inductor 456. According to step 1006 and as depicted in FIG. 23H, the cavity gaps 48 are filled with a dielectric material, then in step 1008 as illustrated in FIG. 23I, the dicing tape 34 is removed, leaving a seventh embodiment of the passive device array 50g with the vertically stacked LC circuit 458 and the capacitors 438.

The capacitors 438 have substantially the same thickness as the substrate 10 overall. The first capacitor 438a includes a first conductive electrode 440a and a second conductive electrode 442a. Each of the conductive electrodes 440, 442 include an upper segment or surface coplanar with the top conductive layer 12, and a lower segment or surface coplanar with the bottom conductive layer 14. Thus, the first conductive electrode 440a is defined by the upper surface 440a-1 and the lower surface 440a-2, while the second conductive electrode 442a is defined by the upper surface 442a-1 and the bottom surface 442a-2. The second capacitor 438b includes a first conductive electrode 440b and a second conductive electrode 42b. The first conductive electrode 440b is defined in part by the upper surface 440b-1 and the bottom surface 440b-2, while the second conductive electrode 442b is defined in part by the upper surface 442b-1 and the bottom surface 442b-2.

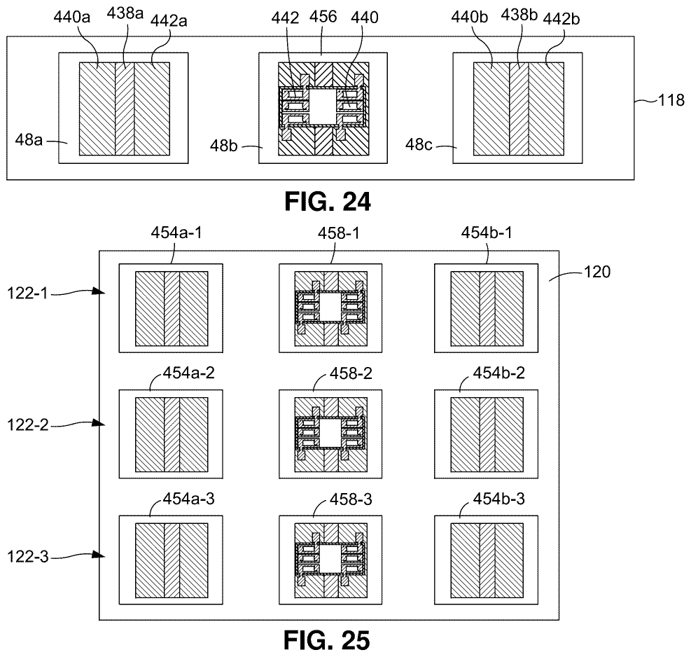

FIG. 24 illustrates a single row array structure 118 that is comprised of the first capacitor 454a, the LC circuit 458, and the second capacitor 454b and showing the uppermost surfaces thereof, including the conductive electrodes 40b, 42b of the inductor 456 that is a part of the LC circuit 458, as well as the first and second electrodes 440a, 442a of the first capacitor 438a, and the first and second electrodes 440b, 442b of the second capacitor 438b. The first cavity gap 48a surrounds the first capacitor 438a, the second cavity gap 48b surrounds the LC circuit 458, and the third cavity gap 48c surrounds the second capacitor 438b.

FIG. 25 shows a 3×3 matrix structure f122 comprised of multiple repeating rows 122 of the single row array structure 118. In a first row 122-1, there is a first capacitor 454a-1, an LC circuit 458-1, and a second capacitor 454b-1. In a second row 122-2, there is a first capacitor 454a-2, an LC circuit 458-2, and a second capacitor 454b-2. In a third row 122-3, there is a first capacitor 454a-3, an LC circuit 458-4, and a second capacitor 454b-4.

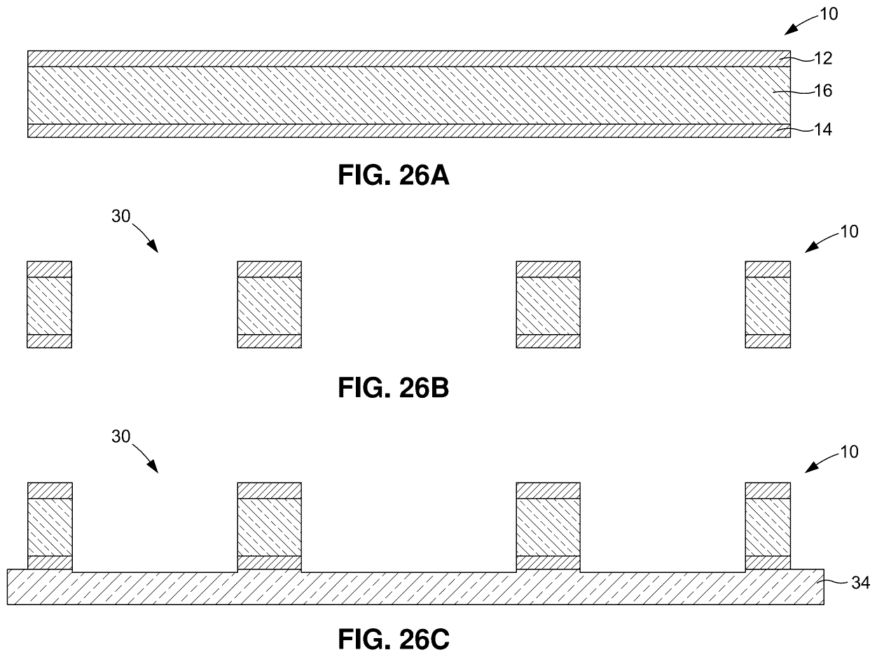

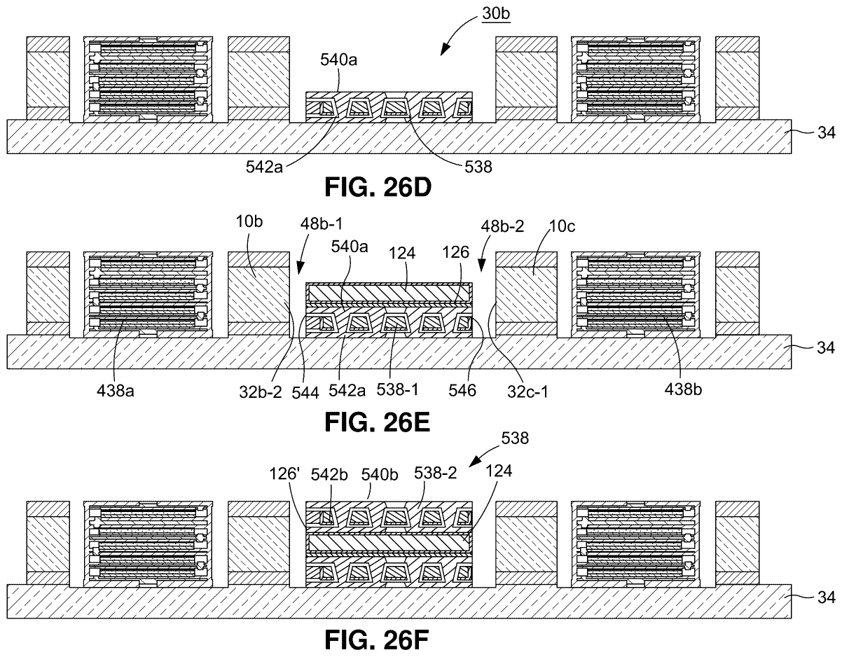

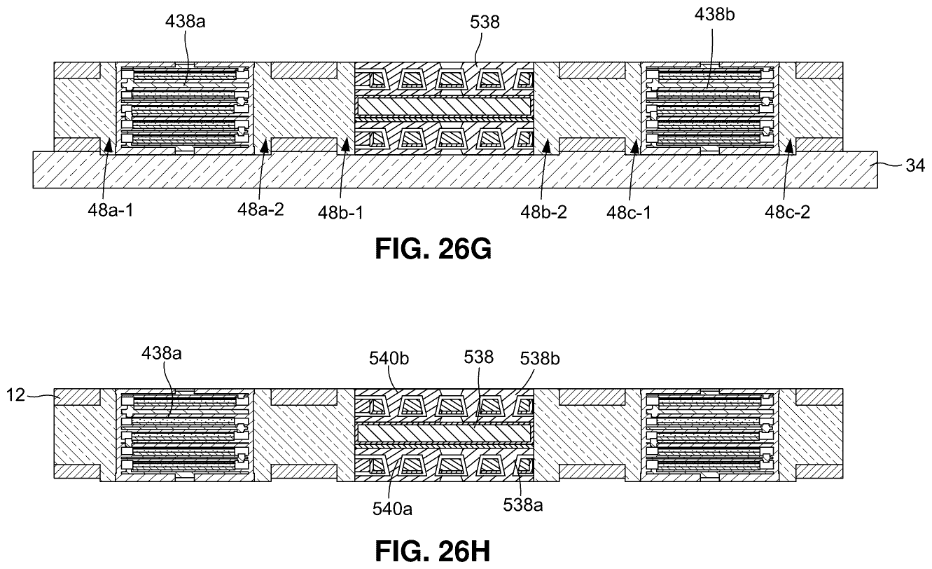

A seventh embodiment of the passive device array 50g may be modified to incorporate an inductor module with an interposed thermal conduction block instead of the LC circuit 458, the details of which are shown in FIGS. 26A-26H. FIG. 26A shows the same double-clad laminate substrate 10 defined by the top conductive layer 12, the bottom conductive layer 14, and the dielectric layer 16 between the top conductive layer 12 and the bottom conductive layer 14. FIG. 26B illustrates the step 1000 of forming the cavities 30 in the double-clad laminate substrate 10. FIG. 26C then shows the dicing tape 34 laminated onto the double-clad laminate substrate 10 in accordance with step 1002.

FIG. 26D shows the next step 1004 of placing the passive devices into the cavities 30. One of the passive devices is a bottom inductor 538a, which includes a first conductive electrode 540a and a second conductive electrode 542a. The bottom inductor 538a is placed within a second cavity 30b and fixed to the dicing tape 34. A left sidewall 544 of the bottom inductor 538a is spaced apart from the right sidewall 32b-2 of the second substrate segment 10b and the right sidewall 546 of the bottom inductor 538a is spaced apart from the left sidewall 32c-1 of the third substrate segment 10c.

FIG. 26E illustrates the placement of the first capacitor 438a within the first cavity 30a, and the placement of the second capacitor 438b within the third cavity 30c. Both the first capacitor 438a and the second capacitor 438b are attached to the dicing tape 34. Because the capacitor 438 has the same configuration as utilized in the sixth embodiment 50f and placed within the respective cavities 30 as described above, the details thereof will be omitted. Additionally, a thermal conduction block 124 is attached to the bottom inductor 538a. In one exemplary embodiment, there may be a layer of thermal interface material (TIM) 126 applied to first conductive electrode 540a of the bottom inductor 538a, atop which the thermal conduction block 124 is placed.

Next, as shown in FIG. 26F, a top inductor 538b is placed onto the thermal conduction block 124. The top inductor 538b includes a first conductive electrode 540b and a second conductive electrode 542b. Like the interface between the bottom inductor 538a and the thermal conduction block 124, there may be another layer of thermal interface material 126′ applied to the thermal conduction block 124. The top inductor 538b may then be placed thereon, with an interface between the second conductive electrode 542b and the thermal interface material 126′/thermal conduction block 124 being defined. The aggregate structure of the bottom inductor 538a, the thermal conduction block 124, and the top inductor 538b may be referred to as an inductor module 538. The top inductor 538b, however, is optional, and alternative embodiments contemplate just the bottom inductor 538a and the thermal conduction block 124. The inclusion or exclusion of the top inductor 538b depends on the needed inductance for a given application.

According to step 1006 and as depicted in FIG. 26G, the cavity gaps 48 are filled with a dielectric material, then in step 1008 as illustrated in FIG. 26H, the dicing tape 34 is removed, leaving an eighth embodiment of the passive device array 50h with the first capacitor 438a, the inductor module 538, and the second capacitor 438b. When fabricated, the inductor module 538 has substantially the same thickness as the substrate 10 overall. Accordingly, the first conductive electrode 540b of the top inductor 538b is exposed, as is the second conductive electrode 542a of the bottom inductor 538a.

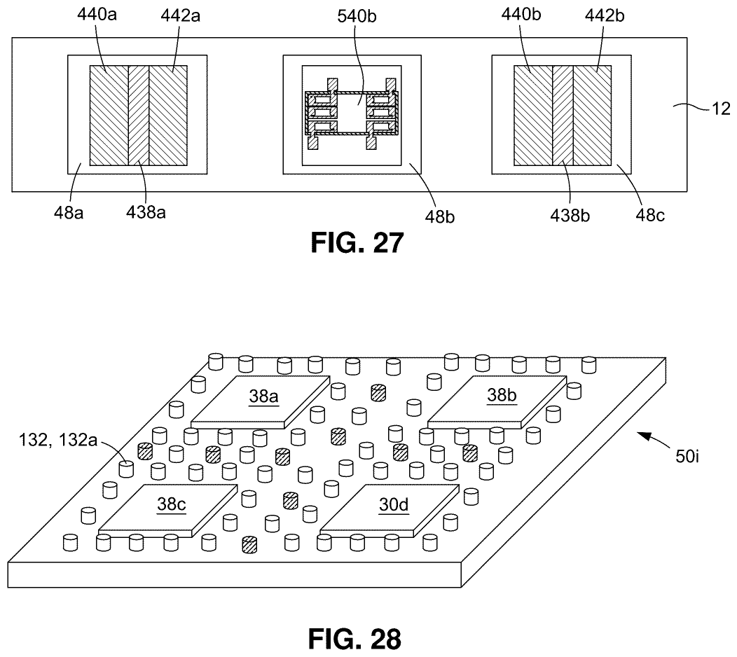

FIG. 27 illustrates an array structure 130 comprised of the first capacitor 438a, the inductor module 538, and the second capacitor 438b, showing the uppermost exposed surfaces thereof including the first conductive electrode 540b of the top inductor 538b, the first and second electrodes 440a, 442a of the first capacitor 438a, and the first and second electrodes 440b, 442b of the second capacitor 438b. The first cavity gap 48a surrounds the first capacitor 438a, the second cavity gap 48b surrounds the inductor module 538, and the third cavity gap 48c surrounds the second capacitor 438b.

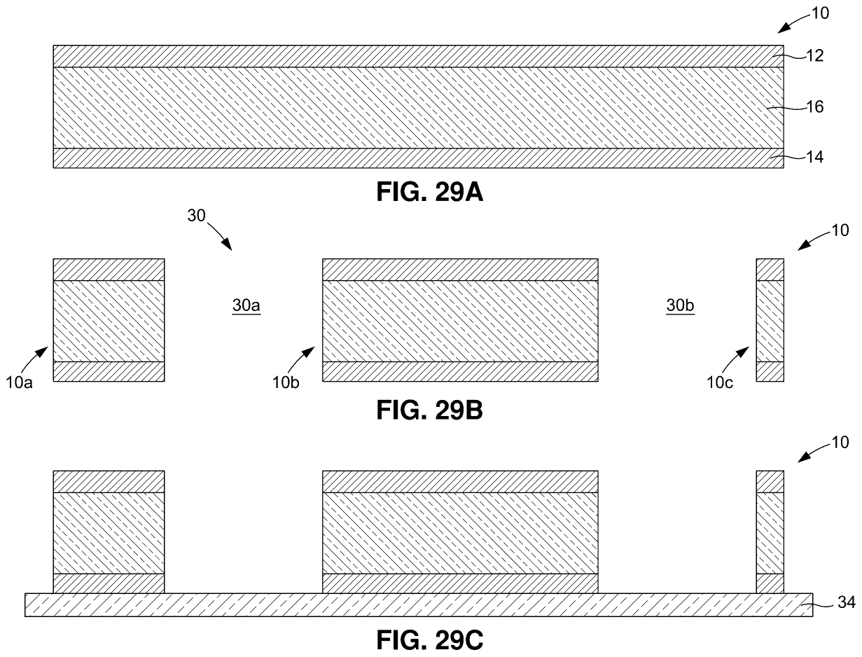

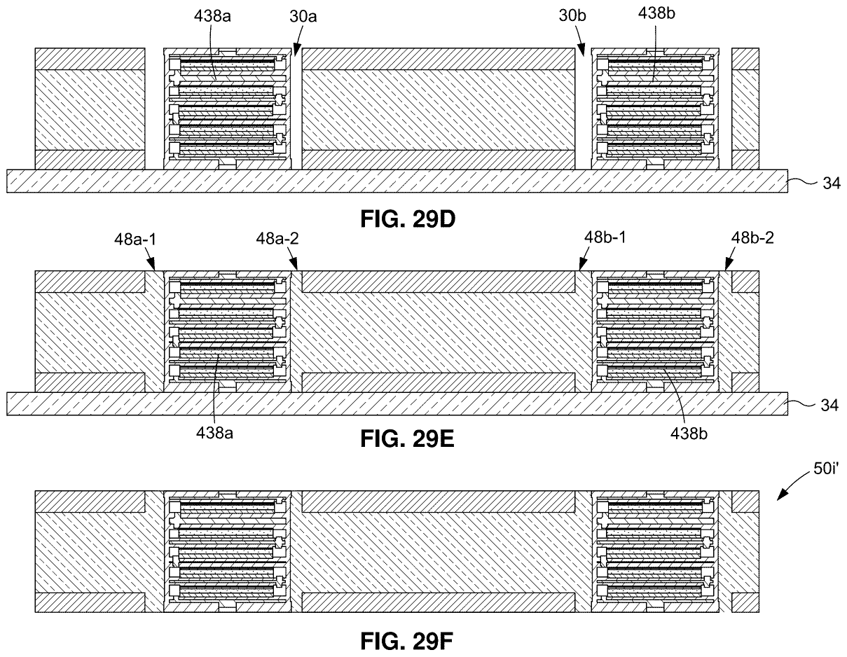

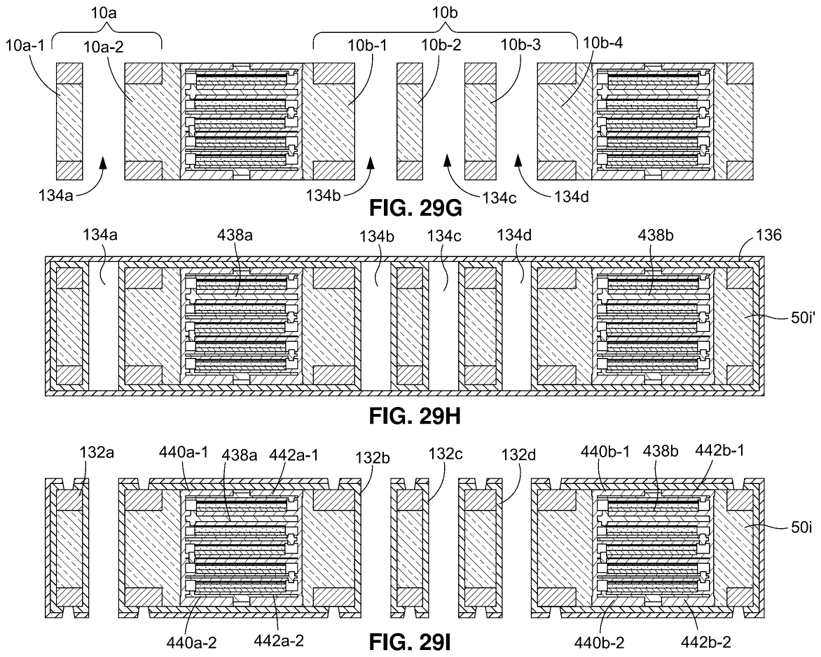

With reference to FIG. 28, the present disclosure additionally contemplates a ninth embodiment of the passive device array 50i, where passive devices 38 are placed on the substrate 10 and multiple vias 132 are defined in the substrate 10. According to this embodiment, the vias 132 are envisioned to dissipate heat that is generated on or around the passive devices 38. It is expressly contemplated that the vias 132 may be used for signal distribution, in addition to the heat dissipation purposes. In this regard, there may be heat-dissipation vias 132a as well as signal transmission vias 132b that are defined in various locations along the substrate 10. The stages in the fabrication process will be described with reference to FIGS. 29A-29I. Beginning with FIG. 26A, there is the double-clad laminate substrate 10 defined by the top conductive layer 12, the bottom conductive layer 14, and the dielectric layer 16 between the top conductive layer 12 and the bottom conductive layer 14. FIG. 29B illustrates the step 1000 of forming the cavities 30 in the double-clad laminate substrate 10. According to this embodiment, there may be a first cavity 30a and a second cavity 30b, which separates the substrate 10 into a first substrate segment 10a, a second substrate segment 10b, and a third substrate segment 10c. The second substrate segment 10b, and to a certain extent, the first substrate segment 10a, are larger in comparison to the cavities 30 of the previously described embodiments, for reasons that will become apparent below.

FIG. 29C shows the dicing tape 34 laminated onto the double-clad laminate substrate 10. FIG. 29D shows the next step 1004 of placing the passive devices/capacitors 438 into the cavities 30. One of the passive devices is the first capacitor 438a that is placed within the first cavity 30a. Another one of the passive devices is the second capacitor 438b that is placed within the second cavity 30b. Both the first capacitor 438a and the second capacitor 438b are attached to the dicing tape 34. The structural features of the capacitors 438, and their relation to the substrate segments 10a-10c have been described above in the context of the eighth embodiment of the passive device array 50h, and will not be repeated for the sake of brevity.

According to step 1006 and as depicted in FIG. 29E, the cavity gaps 48 are filled with a dielectric material, then in step 1008 as illustrated in FIG. 26F, the dicing tape 34 is removed. This results in the ninth embodiment of the passive device array precursor 50i′. Referring to the flowchart of FIG. 1, as well as the cross-sectional view of FIG. 29G in particular, the method for fabrication continues with a step 3000 of forming via cavities 134 in the substrate segments 10a-10c. In the illustrated example, a first via cavity 134a is formed in the first substrate segment 10a, while a second via cavity 134b, a third via cavity 134c, and a fourth via cavity 134d is formed in the second substrate segment 10b. This further separates the first substrate segment 10a into a first substrate section first via segment 10a-1 and a first substrate section second via segment 10a-2. Similarly, the second substrate segment 10b is separated into a second substrate section first via segment 10b-1, a second substrate section second via segment 10b-2, a second substrate section third via segment 10b-3, and second substrate section fourth via segment 10b-4.

FIG. 29H illustrates an outer conductive layer 136 being applied to an entirety of the exposed surfaces of the passive device array precursor 50i′. This outer conductive layer 136 may be applied via a physical vapor deposition (PVD) process, and may be copper or any other suitable electrically and/or thermal conduction material. Additionally, outer conductive layer 136 may be electroplated. The outer conductive layer 136 encompasses the entirety of the via cavities 134 and the internal walls of the various substrate sections thereof. As shown, the outer conductive layer 136 also encompasses the top and bottom surfaces of the substrate segments 10a-10c including the top conductive layer 12 and the bottom conductive layer 14, as well as the previously exposed surfaces of the first and second capacitors 438a, 438b. This includes the upper surface 440a-1 and the lower surface 440a-2 of the first conductive electrode 440a, the upper surface 442a-1 and the lower surface 442a-2 of the second conductive electrode 442a, each of the first capacitor 438a, as well as the upper surface 440b-1 and the lower surface 440b-2 of the first conductive electrode 440b, the upper surface 442b-1 and the lower surface 442b-2 of the second conductive electrode 442b, each of the second capacitor 438b.

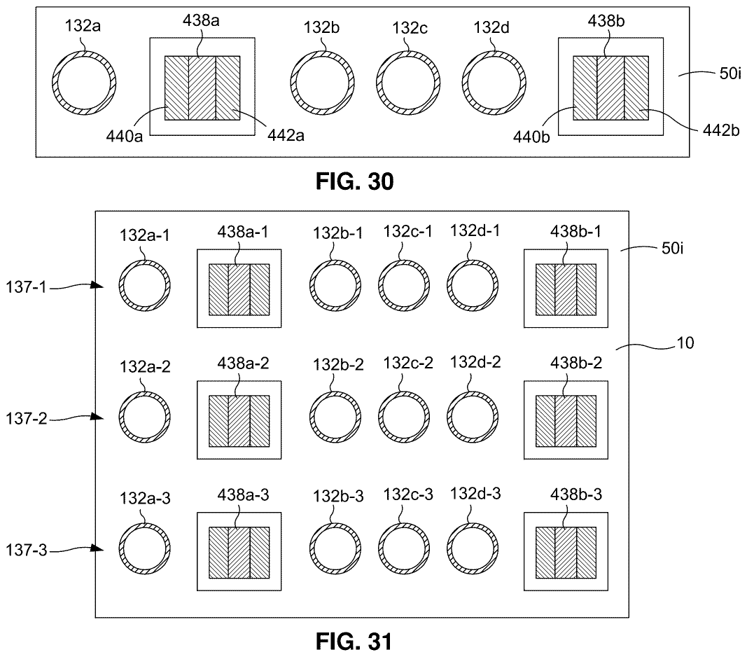

In a step 3004 the vias 132 are isolated via an etching process, the results of which are shown in FIG. 29I and the top view of FIG. 30. In addition to isolating the vias 132, the etching removes those portions of the outer conductive layer 136 that previously covered the upper and lower surfaces of the conductive electrodes 440a, 442a of the first capacitor 438a, and the conductive electrodes 440b, 442b of the second capacitor 438b, thereby exposing those surfaces for connecting access. What remains following the etching/isolation step is the completed ninth embodiment of the passive device array 50i that incorporates the vias 132 and the capacitors 438.

The top view of FIG. 30 illustrates a single row of the passive device array 50i but as shown in FIG. 31, a multiple-row array may also be configured. Multiple repeating rows 137 of the single row array structure are defined on the substrate 10. In a first row 137-1, there is a first via 132a-1, a first capacitor 438a-1, a second via 132b-1, a third via 132c-1, a fourth via 132d-1 and a second capacitor 438b-1. In a second row 137-2, there is a first via 132a-2, a first capacitor 438a-2, a second via 132b-2, a third via 132c-2, a fourth via 132d-2 and a second capacitor 438b-2. In a third row 137-3, there is a first via 132a-3, a first capacitor 438a-3, a second via 132b-3, a third via 132c-3, a fourth via 132d-3 and a second capacitor 438b-3.

The particulars shown herein are by way of example and for purposes of illustrative discussion of the embodiments of the passive device array and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A method for fabricating a customizable passive device array, the method comprising:
forming one or more cavities in a double-clad laminate substrate with a top conductive layer, a bottom conductive layer, and a dielectric layer between the top conductive layer and the bottom conductive layer, the double-clad laminate substrate defining one or more separated top conductive layer segments and one or more separated bottom conductive layer segments;
laminating a dicing tape onto the double-clad laminate substrate;
placing one or more passive devices into a corresponding one of the one or more cavities in the double-clad laminate substrate, the passive devices being affixed to the dicing tape, intermediary gaps being defined between sides of the passive devices and adjacent walls of the double-clad laminate substrate;
filling the intermediary gaps with a dielectric material; and
removing the dicing tape from the double-clad laminate substrate.

2. The method of claim 1, wherein:
each of the passive devices including a first conductive electrode and a second conductive electrode, the first conductive electrode being coplanar with the top conductive layer segments and the second conductive electrode being coplanar with the bottom conductive layer segments.

3. The method of claim 2, wherein the first conductive electrode of each of the passive devices is spaced apart from an adjacent one of the top conductive layer segments, and the second conductive electrode of each of the passive devices is spaced apart from an adjacent one of the bottom conductive layer segments.

4. The method of claim 1, further comprising:
placing or more electrical interconnects each on a respective one of the top conductive electrodes on the one or more passive devices;
establishing one or more connections of conductive terminals of one or more active devices with the electrical interconnects; and
underfilling space between the one or more active devices and the top conductive layer segments and the passive devices.

5. The method of claim 1, wherein at least one of the one or more passive devices is a capacitor.

6. The method of claim 1, wherein at least one of the one or more passive devices is an inductor.

7. The method of claim 1, wherein a first one of the one or more passive devices is an inductor-capacitor (LC) circuit with an LC circuit capacitor and an LC circuit inductor stacked on the LC circuit capacitor.

8. The method of claim 7, further comprising:
placing a thermal conduction block in one of the one or more cavities in the double-clad laminate substrate, additional intermediary gaps being defined between sides of the thermal conduction block and adjacent walls of the double-clad laminate substrate.

9. The method of claim 8, wherein the LC circuit is pre-fabricated prior to placement in the one of the one or more cavities in the double-clad laminate substrate.

10. The method of claim 8, further comprising:
placing one or more metallic passive devices in one or more cavities in the double-clad laminate substrate adjacent to the LC circuit, a given one of the one or more metallic passive devices being either a capacitor or an inductor.

11. The method of claim 1, further comprising:
forming one or more via cavities in the double-clad laminate structure;
depositing dielectric material within the via cavities;
depositing conductive material along the via cavities to define vias; and isolating each of the vias from other vias.

12. A method for fabricating a customizable passive device array, the method comprising:
forming one or more cavities in a double-clad laminate substrate with a top conductive layer, a bottom conductive layer, and a dielectric layer between the top conductive layer and the bottom conductive layer, the double-clad laminate substrate defining one or more separated top conductive layer segments and one or more separated bottom conductive layer segments;
laminating a dicing tape onto the double-clad laminate substrate;
placing a first passive device into a first one of the one or more cavities in the double-clad laminate substrate, the first passive device being affixed to the dicing tape;
stacking a second passive device and the first passive device by deposition of a conductive material over the first passive device and establishing a connection to the second passive device;
underfilling a space between the first passive device and the second passive device;
filling intermediary gaps between a combined structure of the first passive device and the second passive device and adjacent walls of the double-clad laminate substrate defining the first cavity; and
removing the dicing tape from the double-clad laminate substrate.

13. The method of claim 12, further comprising:
placing a thermal dissipation block on the first passive device; and
placing the second passive device on the thermal dissipation block.

14. A configurable passive device array, comprising:
a double-clad laminate substrate with a top conductive layer, a bottom conductive layer, and a dielectric layer between the top conductive layer and the bottom conductive layer, the double-clad laminate substrate defining one or more cavities separating individual top conductive layer segments and individual bottom conductive layer segments; and
one or more passive devices positioned within a respective one of the one or more cavities, each of the one or more passive devices including a first conductive terminal coplanar with and spaced apart from adjacent ones of the top conductive layer segments, and a second conductive terminal coplanar with and spaced apart from adjacent ones of the bottom conductive layer segments.

15. The configurable passive device array of claim 14, wherein the one or more passive devices is a capacitor.

16. The configurable passive device array of claim 14, wherein the one or more passive devices is an inductor.

17. The configurable passive device array of claim 14, further comprising:
one or more electrical interconnects on a top conductive terminal; and
one or more active devices each including active device conductive terminals connected with corresponding ones of the one or more electrical interconnects.

18. The configurable passive device array of claim 14, wherein a first one of the one or more passive devices is an inductor-capacitor (LC) circuit with an LC circuit capacitor and an LC circuit inductor stacked on the LC circuit capacitor.

19. The configurable passive device array of claim 18, further comprising:
a thermal conduction block in one of the one or more cavities in the double-clad laminate substrate, additional intermediary gaps being defined between sides of the thermal conduction block and adjacent walls of the double-clad laminate substrate.

20. The configurable passive device array of claim 18, further comprising:
one or more metallic passive devices disposed in one or more cavities in the double-clad laminate substrate adjacent to the LC circuit, a given one of the one or more metallic passive devices being either a capacitor or an inductor.
